(19) United States
(12) Patent Application Publication
(10) Pub. No.: US 2012/0151302 A1
(43) Pub. Date: Jun. 14, 2012

(54) BROADCAST MULTIMEDIA STORAGE AND ACCESS USING PAGE MAPS WHEN ASYMMETRIC MEMORY IS USED

(75) Inventors: Michael G. Luby, Berkeley, CA (US); Thadi M. Nagaraj, San Diego, CA (US)

(73) Assignee: QUALCOMM Incorporated, San Diego, CA (US)

(21) Appl. No.: 13/206,418

(22) Filed: Aug. 9, 2011

Related U.S. Application Data
(60) Provisional application No. 61/421,984, filed on Dec. 10, 2010.

(51) Int. Cl. H03M 13/09

(52) U.S. Cl. 714/776; 714/E11.034

(57) ABSTRACT

A receiving device for storing and accessing data transmitted from a source, the data generated from transport objects comprises multimedia content that uses a forward error correction code, is subject to network losses, and/or is transported interleaved. The device includes a receiving module configured to store the data in first access memory according to a page format, write the data formatted as pages to physical storage media, and generate a page structure map describing a relationship between the data written and a data structure of the multimedia content. An access module receives a request for a portion of the multimedia content, determines pages of data from the physical storage medium as including data corresponding to the requested portion according to the page structure map, stores the determined pages, and decodes the data corresponding to the requested portion from a requesting module. A media player receives the requested portion for consumption.

### CROSS-REFERENCES

This application claims priority from and is a non-provisional of U.S. Provisional Patent Application No. 61/421,984 filed Dec. 10, 2010 entitled “Broadcast Multimedia Storage and Access” which is hereby incorporated by reference, as if set forth in full in this document, for all purposes.

The following references are included here and are incorporated by reference in their entirety for all purposes:

U.S. patent application Ser. No. 12/197,993, filed Aug. 25, 2008, entitled “File Download and Streaming System;” and

U.S. patent application Ser. No. 12/859,161, filed Aug. 18, 2010, entitled “Methods and Apparatus Employing FEC Codes with Permanent Inactivation of Symbols for Encoding and Decoding Processes.”

### BACKGROUND

The present invention relates to systems and methods for delivering broadcast streaming data, and more particularly to systems and methods for storing and accessing broadcast multimedia streaming data with forward error correction (“FEC”).

Forward error correction is useful as it provides information to a receiver that allows the receiver to recover from errors in data transmission. Various techniques for FEC are known. FEC has been used with streaming systems to provide for error correction while dealing with the nature of streams.

One typical nature of a stream is that data is received at a transmitter and must be transmitted before the transmitter receives all of the data or knows definitively how much data is to be transmitted. This is not a requirement, as a file (a set of data elements of a known size that might be available in its entirety to the transmitter at the outset of transmission or transmit data generation) might be processed as if it were a stream. However, the design of a transmitter (and receiver in a communication system) where streams are expected might be a design that includes dealing with transmitting data without knowing the size of the data set to be transmitted or having it available for taking into account in generating the data to be transmitted. Typically, when data is processed as a stream it is expected that the process will proceed apace in real-time or near real-time, i.e., that a transmitter will process data as it is received and transmit the processed data as it becomes available.

One FEC streaming architecture is that based on RFC (“Request For Comments”) 2733. [RFC2733] describes a basic method for applying a specific FEC erasure code to protect an RTP (“Real-Time Protocol”) stream against packet loss. With such FEC applications, source packets are padded out to the uniform length for the purpose of generating repair packets from source packets. Thus, even when the lengths of all source packets vary dramatically in size, the size of a repair packet is the maximum of the size of all source packets it is generated from. This can cause wastage of bandwidth for transmitting repair packets. For example, if the maximum size of a source packet that a repair packet is generated from is 1,000 bytes in length, then the repair packet will be around 1,000 bytes in length (the repair packet is actually a couple of bytes longer than the maximum source packet). However, if one of the other source packets that the repair packet is generated from is, for example, 300 bytes in length and this source packet is lost, then the repair packet of over 1,000 bytes is used to recover the missing 300 byte source packet, resulting in over 700 of the bytes of the repair packet to be wasted, which results in wasted transmission bandwidth since the repair packet is transmitted.

The byte unit of measure is used in examples and explanations herein. A byte generally refers to eight bits of data. In some computer architectures, a byte may be seven bits or nine bits, or some other unit of data measurement may be appropriate. In some contexts, the term “octet” is used to denote eight bits instead of “byte”, and in general, the two terms can be used interchangeably. Unless otherwise indicated, it should be understood that the unit of measurement used to measure data size is not crucial. Larger groupings of memory storage might be referred to as a “kilobyte” (or “KB”), referring to 1,024 bytes, a “megabyte” (or “MB”), referring to 1,048,576 bytes, or a “gigabyte” (or “GB”), referring to 1,073,741,824 bytes. The exact number is not important, unless otherwise indicated and in some contexts, KB, MB and GB might refer to numbers smaller or larger than those stated here.

Flash memory has become pervasive as the primary non-volatile memory (“NVM”) physical storage medium for computers and mobile devices. A comparison of disk-based NVM and flash-based NVM can be found, for example, in [Lee and Moon]. Flash memory has several advantages and disadvantages over other types of memory.

The advantages are many, e.g., the ability to resist shocks and the fast random-access read times. For example, it is generally almost as fast (typically within 10%) to read a sequence of pages of data in non-sequential locations from flash memory into RAM as it is to read an equal number of pages of data in sequential locations from flash memory into RAM, where a page can be 512 bytes, 2,048 bytes, or 4,096 bytes, for example, and depends on the type of flash memory. As an example, if 256 pages of 1 KB each of data can be read from consecutive locations in flash memory in T seconds, then the time for reading 256 pages of 1 KB pages of data from arbitrary non-consecutive locations in the flash memory might be around 1.1*T.

One disadvantage of flash memory is that erasing/writing of memory is typically only efficient if large blocks of data are written to sequentially located pages, since it is time-expensive to write small pages of data to arbitrary locations in flash memory, where a block can be 128 KB or 256 KB, for example, and depends on the type of flash memory. For example, writing a sequence of pages into arbitrary locations to flash memory can be many times slower than writing a sequence of consecutively located pages into flash memory, e.g., hundreds of times slower. Typically, reading from flash memory is faster than writing to flash memory, even when comparing sequential reading of arbitrary pages of data from flash memory to writing consecutive large blocks of data to flash memory. Furthermore, before writing to a block of memory, the block needs to be erased all at once as an entire block before the block can be written to again (this property is the origin of the “flash” name used for this technology).

Another disadvantage of flash memory is that there is a limited number of erasures that a flash memory can support before it wears out, e.g., several thousand times, or hundreds of thousands of times, or a million times or more, depending on the conditions of the environment it is embedded into and the type of flash memory technology in usage, and other factors. Other physical storage medium has similar properties.

When broadcasting objects to receivers, typically it is the case that the reliable recovery of the entire object is desired, and often application layer forward error correction codes (AL-FEC codes) are employed to provide reliability. Examples of AL-FEC codes are described in [Raptor-RFC5053], [RaptorQ-RFC6330], and [LDPC-RFC5170]. The use of AL-FEC is to generate encoded data using an FEC code from the file, put the encoded data into packets and send the packets. Depending on the FEC code and how it is used, receivers can reliably recover the file as long as enough of the encoded data is received.

When AL-FEC is employed, due to memory concerns at the sender and/or receivers, for larger files the source data of the file is often partitioned into multiple source blocks, the FEC code is applied to each source block independently of other source blocks, and the encoded data generated for each source block is transmitted. To maximize efficient usage of network transmission resources, it is often the case that the encoded data for the source blocks is sent in an interleaved pattern, and that the source blocks are chosen to be as large a size as possible. The reason for this is that this ensures that packet loss is spread as equally amongst the encoded data for the different source blocks as possible, and that the amount of loss that the encoded data for each source block experiences is as close as possible to the same amount as for every other source block.

Some FEC broadcast solutions, such as those described in [LDPC-RFC5170], use an amount of access memory (RAM) that is at least the size of a source block to decode each source block. Since the amount of RAM that is available at a receiver is typically quite limited, other FEC broadcast solutions, such as those described in [Raptor-RFC5053], describe methods for concurrently using large source blocks while at the same time requiring much smaller amounts of RAM to decode, using sub-blocking. A straightforward way of implementing a delivery solution based on sub-blocking is to receive packets, each of which contain encoded sub-symbols for multiple sub-blocks, and then for each sub-block write the sub-symbols for that sub-block to a temporary file in NVM. In this case, recovering the file consists of processing the sub-blocks sequentially from the beginning of the file to the end, where for each sub-block processing consists of reading into RAM the temporary file corresponding to the sub-block and then using the encoded sub-symbols of the temporary file to decode the original sub-block, and then writing the appending the original sub-block to a file in NVM that stores the recovered file. Thus, the amount of RAM needed for decoding when sub-blocking is used is proportional to the sub-block size, which can be much smaller than the source block size.

There are some potentially unappealing aspects to this straightforward method of using sub-blocking. For example, the number of files that can be concurrently open and be written to by the receiving device can be limited by the receiving device file system, which can limit the number of sub-blocks into which the file is partitioned. Some file systems may for example allow only 10 files to be open concurrently. As another example, if the file is a video file, the entire video file is recovered before the end user can view the video file on the device, and during the recovery large amounts of data is read-from and written-to flash memory. This recovery process can provide an unsatisfactory experience to end users who must wait to view the media content of the file until after the recovery process finishes, can use resources that are contending with other concurrently running processes, and can cause the total amount of data written to flash memory to be twice the video file size. Furthermore, it is often the case that a large portion of the multimedia material that is received in a broadcast is never viewed by the end user, and thus the process of proactively decoding all of the received multimedia material that is received in a broadcast session can unnecessarily waste the resources at the receiver, e.g., the CPU resources, the flash memory resources, and the system I/O resources, that can ultimately unnecessarily use up battery power, wear out the flash memory, unnecessarily use up storage space in the flash memory, and provide the end user with an unsatisfactory streaming experience.

What is needed are better receiver methods for processing broadcast encoded data generated from media files, that provides network efficiency, that utilizes the flash memory in more efficient ways, that more efficiently utilizes CPU and I/O resources, that minimizes the number of open files, and that provides a superior user experience.

### REFERENCES

[3GPP TS 26.247] 3GPP Specification TS 26.247 (“Transparent End-to-End Packet-Switched Streaming Service (PSS); Progressive Download and Dynamic Adaptive Streaming over HTTP (3GP-DASH)”.

[ISO/IEC 23001-6] ISO/IEC 23001-6.

[ISO/IEC 14496-12] ISO/IEC 14496-12.

[LDPC-RFC5170] Roca, V., Neumann, C., and Furodet, D., “Low Density Parity Check (LDPC) Staircase and Triangle Forward Error Correction (FEC) Schemes,” IETF Request for Comments RFC-5170 (June 2008).

[Lee and Moon] Lee, S.-W., and Moon, B., “Design of Flash-Based DBMS: An In-Page Logging Approach,” Proceedings of the 2007 ACM SIGMOD International Conference on Management of Data, pp. 55-66 (2007).

[Matsuoka et al.] Matsuoka, H., Yamada, A., and Ohya, T., “Low-Density Parity-Check Code Extensions Applied for Broadcast-Communication Integrated Content Delivery”, Research Laboratories, NTT DOCOMO, Inc. 3-6, Hikari-no-oka, Yokosuka, Kanagawa, 239-8536, Japan.

[RaptorQ-RFC6330] Luby, M., Shokrollahi, A., Watson, M., Stockhammer, T., and Minder, L., “RaptorQ Forward Error Correction Scheme for Object Delivery,” IETF Request for Comments RFC-6330 (August 2011).

[Raptor-RFC5053] Luby, M., Shokrollahi, A., Watson, M., and Stockhammer, T., “Raptor Forward Error Correction Scheme for Object Delivery,” IETF Request for Comments RFC-5053 (September 2007).

[RFC2733] Rosenberg, J., and Schulzrinne, H., “An RTP Payload Format for Generic Forward Error Correction,” IETF Request for Comments RFC-2733 (December 1999).

### SUMMARY

An receiving device for storing and accessing data transmitted from a source to the receiving device over a communications channel, where the data generated from a plurality of transport objects comprising multimedia content that uses a forward error correction code, that is subject to network losses, and/or that is transported in an interleaved fashion, according to the disclosure includes a receiving module configured to receive the data as data packets, store the data in first access memory of the receiving module according to a page format, write the data formatted as pages sequentially from the first access memory to a file in physical storage media, and generate a page structure map describing a relationship between the data written to the file in the non-volatile memory and a data structure of the multimedia content; the non-volatile memory communicatively coupled to the receiving module and configured to store in the file the data formatted as pages written from the first access memory of the receiving module; an access module communicatively coupled to an application module and the physical storage medium and configured to receive a request for a portion of the multimedia content from the application module, determine pages of data read from the file in the non-volatile memory as including data corresponding to the requested portion of the multimedia content according to the page structure map, read the determined pages from the physical storage medium into the second access memory of the access module, and decode the data corresponding to the requested portion of the multimedia content using the forward error correction code to recover the requested portion of the multimedia content from the access module and provide the requested portion of the multimedia content to the application module.

A method for storing and accessing data transmitted from a source to a destination over a communications channel, the data transmitted as data packets generated from multimedia content includes receiving the data as data packets; storing the data in first access memory according to a page format; writing the data formatted as pages from the first access memory to a file in non-volatile memory; generating a page structure map describing a relationship between the data written to the file in the non-volatile memory and a data structure of the multimedia content; receiving a request for a portion of the multimedia content; storing in a second access memory pages of data read from the file in the non-volatile memory, wherein the pages stored are determined according to the page structure map as including data corresponding to the requested portion of the multimedia content; decoding the data corresponding to the requested portion of the multimedia content using the forward error correction code; and providing the requested portion of the multimedia content for consumption.

Depending upon the embodiment, one or more benefits may be achieved. Benefits are provided in detail throughout the present specification and more particularly below. A further understanding of the nature and the advantages of the inventions disclosed herein may be realized by reference to the remaining portions of the specification and the attached drawings.

### BRIEF DESCRIPTION OF THE DRAWINGS

FIG. 1 is a block diagram of a broadcast delivery system.

FIG. 2 is a block diagram of a receiving device for a broadcast file delivery system.

FIG. 3 is a block diagram of a receiving device for a broadcast storage and access system.

FIG. 4 is an illustrative embodiment of a receiving process for a broadcast storage and access system.

FIG. 5 is an illustrative embodiment of an access process for a broadcast storage and access system.

FIG. 6 is an illustrative embodiment of the logic of a receiving process for a broadcast storage and access system.

FIG. 7 is an illustrative embodiment of the logic of an access process for determining source block information for a broadcast storage and access system.

FIG. 8 is an illustrative embodiment of the logic of an access process for determining sub-block information for a broadcast storage and access system.

FIG. 9 is an illustrative embodiment of a page structure map that can be generated by the receiving process shown in FIG. 6.

FIG. 10 is an illustrative embodiment of the logic of an access process for reading data of a sub-block for a broadcast storage and access system.

FIG. 11 is an illustrative embodiment of a received sequence of packets and the resulting source block ESI lists and page structure map.

FIG. 12 is an illustrative embodiment of some of the pages written to flash NVM corresponding to FIG. 11.

FIG. 13 is an illustrative embodiment of the status of the buffers within the access process corresponding to FIG. 11.

FIG. 14 is an illustrative embodiment of a broadcast storage and access system with the storage and access functionality spread across different receiver devices.

### DETAILED DESCRIPTION

As used herein, the term “stream” refers to any data that is stored or generated at one or more sources and is delivered at a specified rate at each point in time in the order it is generated to one or more destinations. Streams can be fixed rate or variable rate. Thus, an MPEG video stream, AMR audio stream, and a data stream used to control a remote device, are all examples of “streams” that can be delivered. The rate of the stream at each point in time can be known (such as 4 megabits per second) or unknown (such as a variable rate stream where the rate at each point in time is not known in advance). Either way, the stream is a sequence of input bits, where each bit has a position in the stream and a value.

Transmission is the process of transmitting data from one or more senders to one or more receivers through a channel in order to deliver a file or stream. If one sender is connected to any number of receivers by a perfect channel, the received data can be an exact copy of the input file or stream, as all the data will be received correctly. Here, it is assumed that the channel is not perfect, which is the case for most real-world channels. Of the many channel imperfections, two imperfections of interest are data erasure and data incompleteness (which can be treated as a special case of data erasure). Data erasure occurs when the channel loses or drops data. Data incompleteness occurs when a receiver does not start receiving data until some of the data has already passed it by, the receiver stops receiving data before transmission ends, the receiver chooses to only receive a portion of the transmitted data, and/or the receiver intermittently stops and starts again receiving data. As an example of data incompleteness, a moving satellite sender might be transmitting data representing an input file or stream and start the transmission before a receiver is in range. Once the receiver is in range, data can be received until the satellite moves out of range, at which point the receiver can redirect its satellite dish (during which time it is not receiving data) to start receiving the data about the same input file or stream being transmitted by another satellite that has moved into range. As should be apparent from reading this description, data incompleteness is a special case of data erasure, since the receiver can treat the data incompleteness (and the receiver has the same problems) as if the receiver was in range the entire time, but the channel lost all the data up to the point where the receiver started receiving data. Also, as is well known in communication systems design, detectable errors can be considered equivalent to erasures by simply dropping all data blocks or symbols that have detectable errors.

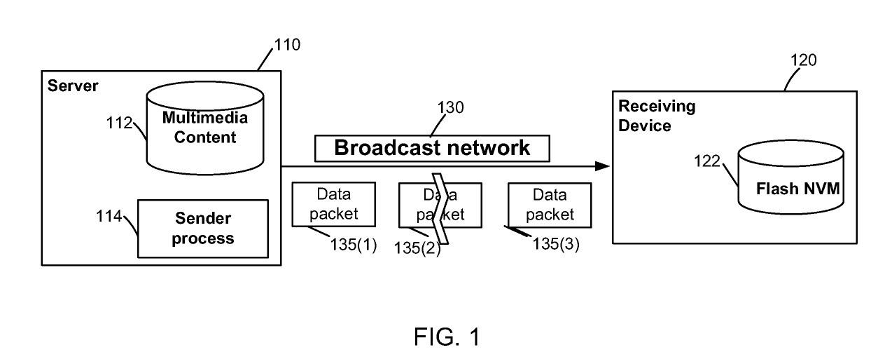

The general scenario is the usage of a broadcast network to deliver multimedia content to end devices, so that end users can view selected portions of the multimedia content whenever they would like. FIG. 1 shows a diagram of a broadcast delivery system. A server (110) is equipped with storage (112) for storing multimedia content, and a sender process (114). A server (110) transmits data packets (135(1), 135(2), 135(3)) generated from the multimedia content by the sender process over a broadcast network (130), where there might be many receiving devices that can receive some or all of the transmitted packets. A receiving device (120) receives data packets (135(1), 135(2), 135(3)) from the broadcast network (130), where some of the packets might not be received at the receiving device for a variety of reasons (e.g., 135(2) is lost, for some reason).

Generally, the multimedia content comprises multiple transport objects that are transmitted non-sequentially, i.e., data transmitted for at least some of the transport objects is interleaved with data transmitted for other transport objects. In addition, it is often the case that to protect against not receiving at least some of the transmitted packets, for at least some of the transport objects at least some of the transmitted data is generated from the transport objects using an FEC code. In some cases, the same pattern of FEC data is generated and transmitted for multiple transport objects, e.g., when the multiple transport objects comprise sub-blocks of a source block. In other cases, the FEC data is generated and transmitted independently for different transport objects, e.g., when the different transport objects are the different source blocks of a file, or when the different transport objects are different multimedia files.

The multimedia content might be episodes of television programs, or might be a concatenation of advertisements. Which portions are selected and when they are selected can depend on a variety of factors. For example, end users may be sampling different portions of the multimedia content, skipping around forward and backwards to particular scenes of the show. As another example, the multimedia content may be the concatenation of many advertisements, and then user preferences can be used to decide which advertisements may be shown interspersed within programming that the end user is viewing, where the timing of when the advertisements are accessed and viewed depends on the breaks in the programming.

To make it simple to describe, an end user is viewing multimedia content, where a multimedia player is providing the multimedia content that is to be viewed and processes it and displays it in a viewable format on a screen. There are many alternatives, i.e., viewing could be listening to music, and a multimedia player could be a converter from digital audio data to speakers on the end device. The multimedia data may also be a data stream, and the end user may be another program that is querying the data stream to extract statistics, and the portions of the data stream that are viewed may be determined by the statistics extracting program. There are many other variants, as one skilled in the art understands.

The term “multimedia content” as used herein might refer to the singular or the plural, depending on context. In some contexts, “multimedia” might refer to one piece of content that uses multiple media, such as video that is combined with audio, text that is combined with images, images that are combined with audio, text, images and/or video that are combined with structured text or instructions (e.g., XML sequences) or the like. In other contexts, multimedia content might be a single medium, but the multimedia sender and/or multimedia player might be set up to send at other times content in other media. Examples of multimedia content include a movie, a slide show, a computer presentation, an audio file, a game, images, etc. A given multimedia content might be transported by logically dividing the content into transport objects.

Flash NVM is only used as an example of a type of NVM. There are many other types to which the methods described herein could equally apply.

Broadcast is only an example network to which the methods described herein could apply. In some embodiments, the network may be multicast, or unicast. For example, one or more concurrent HTTP/TCP connections could be used by a client to request and have different parts of a content object delivered from different sources. As another example, such a client could receive portions of the content via a broadcast or multicast enabled network and request and receive other parts of the same content via HTTP/TCP connections.

In some embodiments described below, the usage of FEC is not required to obtain at least some of the benefits of the methods and processes described herein. In such embodiments, data might be interleaved with or without FEC.

Some of the methods described herein can be used to achieve the above desirable characteristics. In a preferred embodiment, the methods involve a novel combination of the characteristics of FEC sub-blocking, flash NVM, and multimedia indexing. FEC sub-blocking is described in [Raptor-RFC5053] and [RaptorQ-RFC6330]. The relevant characteristics of flash NVM are well-known. The relevant type of multimedia indexing is for example similar to the Sidx described in [3GPP TS 26.247], and in [ISO/IEC 23001-6] and [ISO/IEC 14496-12] (these documents refer to the “DASH Standard”). The sender of the multimedia content generates the data to be broadcast using an application layer forward error correction code (AL-FEC) embedded into an AL-FEC broadcast object delivery framework such as that explained in [Raptor-RFC5053] or [RaptorQ-RFC6330].

An important feature of the methods described herein is to leverage the sub-blocking feature offered by [Raptor-RFC5053] and [RaptorQ-RFC6330]. As described below, these methods can be especially effective when the NVM is flash NVM, or NVM with characteristics similar to flash NVM.

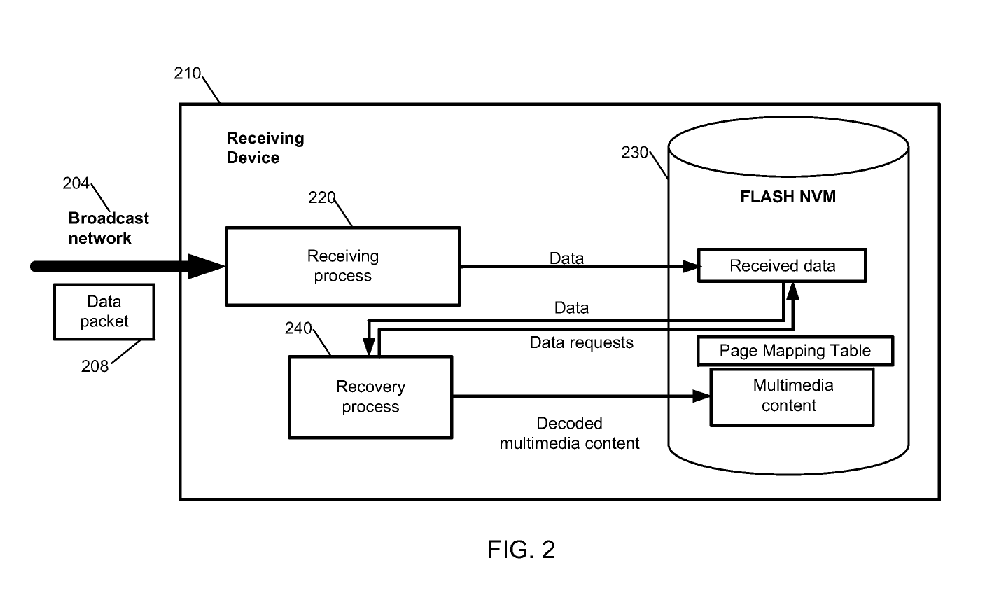

A broadcast file delivery system (hereafter sometimes abbreviated to “BFDS”) is described with reference to FIG. 2, which shows a receiving device (210) receiving data packets (208) from a broadcast network (204). Within the receiving device (210) there is a receiving process (220), a recovery process (240), and flash NVM (230). The receiving process (220) and the recovery process (240) together are used at a receiver to receive data packets (208) received over the broadcast network (204) for multimedia content, and to recover and write the original multimedia content to flash NVM (230) as a file. The received broadcast data (208) for each source block is stored in flash NVM (230) as the data arrives by the receiving process (220). In other implementations—see below—an access process is distinct from the recovery process (i.e., where there is an access process that gets the requested data and decodes it, and a requesting process that translates—if necessary—the user requests into specific portions of multimedia objects).

Once enough data has arrived to recover the multimedia content, the recovery process (240) recovers each source block sequentially one sub-block at a time and writes the recovered original multimedia content into a file within the flash NVM (230). The recovery process (240) processes each sub-block as follows: the received data stored in flash NVM (230) for the sub-block is read into RAM, the sub-block is decoded based on this data, and then the recovered original sub-block is written back to the flash NVM (230) into a file containing the multimedia content. In the above, the transport objects comprise the sub-blocks of the source blocks, and the data transmitted for the sub-blocks in an interleaved order is the source and FEC repair sub-symbols of the sub-blocks.

An important issue is how the data is written to and read from NVM by a conventional implementation of a broadcast file delivery system. A conventional way to do this is for the receiving process (220) to use a temporary file for each sub-block to store the sub-symbols for that sub-block in the flash NVM (230), and the temporary file for the sub-block is read in when a sub-block is to be decoded and stored back to flash NVM (230) in the recovery process (240). In some receiver devices this can be an effective strategy, but in other receiver devices this solution may be less attractive, i.e., when there is a file system limitation on the number of files that are allowed to be concurrently open that is less than the desired number of sub-blocks, or when there is a performance penalty when a large number of files are concurrently open. In these cases, there can be significant advantages to a different methodology for storing the received data, as described in more detail below.

The methods disclosed below for implementing a preferred BFDS take advantage of the asymmetric properties of the flash NVM characteristics, and in particular the ability to be able to efficiently read arbitrary pages of data from flash NVM but taking into account that writing to flash NVM is typically only efficient if each write is of a larger block of consecutive data. As described in more detail below, the multimedia content is partitioned into many sub-blocks, or equivalently transport objects, and these sub-blocks are delivered to the receiving process in an interleaved order, the receiving process (220) can be implemented to write all the received data for all the transport objects comprising that multimedia content, received in interleaved order, into a single data file in flash NVM, such that a large block of received data is written to consecutive positions within the data file during each write, and such that the data is written in such a way that each page of flash NVM contains data associated with a single sub-block, or equivalently transport object.

Advantages of a preferred broadcast file delivery system include high network efficiency due to the usage of large source blocks in the transmission, low RAM memory usage to recover the multimedia content due to the usage of sub-blocking, usage of a limited number of files, and efficient writing and reading of data between the RAM and the flash NVM due to the pattern of reading and writing between the RAM and flash NVM employed by the processes.

Although a preferred BFDS provides many benefits over conventional BFDS systems, there are additional improvements described below that can be made that provide additional benefits. Some desirable characteristics for broadcast delivery and consumption of multimedia content on an end device are the following: (1) minimal reception overhead, (2) minimal number of flash NVM files, (3) one-time write, (4) near instantaneous viewing, and (5) minimal reads.

For minimal reception overhead, and maximum robustness to loss, the amount of received broadcast data needed to be able to play back any portion of the multimedia content thereafter should be equal to the total size of the multimedia content. This should be true even when significant arbitrary portions of the transmitted data for the multimedia content never arrive at the receiver, when there is significant packet loss and when the distribution of loss is can be bursty or random or any other pattern of loss.

For minimal number of flash NVM files, the number of flash NVM files used for each multimedia file should be minimized, i.e., one flash NVM file to store the data associated with a multimedia file is preferable. In some embodiments, one flash NVM file may be used to store multiple multimedia content objects, i.e., data that is at least loosely concurrently received may comprise multiple unrelated or related multimedia contents, e.g., multimedia contents corresponding to different movies, or to the video and audio of a given television show, etc.

For one-time write, the received broadcast data can be written to the flash NVM using sequential writes as it is received, and these are the only writes to flash NVM needed for this multimedia content. No additional reading and writing from flash NVM is needed in order to pre-process the data prior to reading from flash NVM and consuming relevant portions of the multimedia content.

For near instantaneous viewing, it is perceptually instantaneous between when an end user issues a command to view a portion of multimedia content at a particular starting point and the time when the multimedia player starts display of that portion at that starting point. Once the display has started, the display continues seamlessly with no pauses for as long as desired by the end user or until the remainder of the content has been consumed.

For minimal reads, the total amount of data that is read from the flash NVM over all viewings of portions of the multimedia content is essentially equal to the aggregate size of the consumed portions of the multimedia content, where an amount of data proportional to the amount of consumed multimedia content can be read from the flash NVM and fed to the multimedia player.

A preferred broadcast file delivery system (BFDS) provides benefit (1) and (2) listed above, and also minimizes the amount of needed RAM, and may be preferred for general delivery of files of any format to the receiver. In the context of delivering and viewing multimedia content, the additional benefits (3), (4) and (5) can be provided by the broadcast multimedia storage and access system described below herein. Furthermore, one important application of a broadcast multimedia storage and access system is that it can be used to implement a preferred BFDS, as described in more detail below.

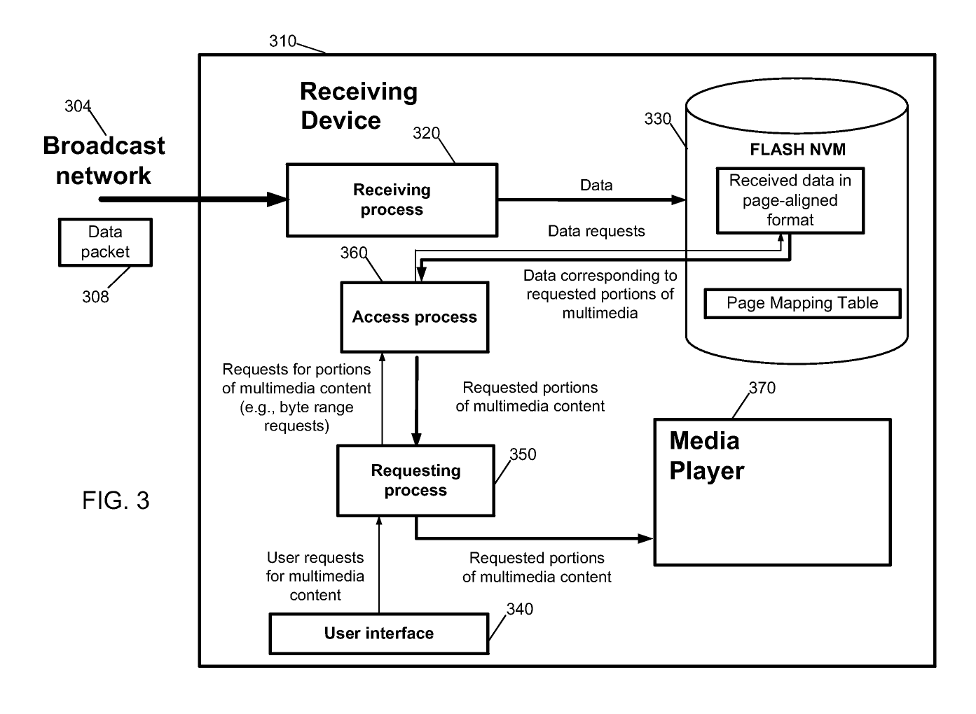

A broadcast multimedia storage and access system (hereafter sometimes abbreviated to “BMSAS”) is described with reference to FIG. 3, which shows a receiving device (310) that employs a receiving process (320) similar to the receiving process (220) for the broadcast file delivery system, a requesting process (350), and an access process (360). The requesting process (350) provides requests for portions of multimedia content to the access process (360), and the access process (360) in response provides the requested portions of the original multimedia content to the requesting process (350).

The receiving process (320) in some embodiments might be the combination of a separate data receiving process and a data writing process, wherein the data receiving process receives the data to be written from a network or over an internal interface or some other interface, and wherein the data writing process determines how to partially de-interleave received data and write the data in a page-aligned manner to flash NVM, or similar storage media.

A BMSAS is general purpose and can provide many different functions to different applications. As an example of a BMSAS configuration, the requesting process (350) may be controlled by a user interface process (340) and may be providing multimedia content to a media player (370). Alternatively, the requesting process (350) may interface with a data analysis program, or by some other process that is controlled by the end user or by an internal application within the receiver device that desires quick access to contiguous portions of the original multimedia content. As another alternative, a BMSAS may be configured to support the functionality of a preferred BFDS, wherein the requesting process (350) requests the multimedia content sequentially from the beginning from the access process (360), and writes the multimedia content into a file in the flash NVM as the multimedia content arrives from the access process (360). In this alternative, the requesting process may only request to recover a particular multimedia content when there is a high likelihood that the multimedia content will be later consumed or viewed at least once by some other application. Other multimedia content that is less likely to be consumed or viewed might be requested and accessed only near or during the time when the multimedia content is to be consumed. Other multimedia content that is never consumed or viewed may never be requested or accessed even though at least some of the data that would allow recovery of that multimedia content is stored in the flash NVM by a receiving process.

As another example of a BMSAS configuration, the requesting process (350) may be on another device distinct from the receiving device (310) that hosts the access process (360) and upon which the broadcast data for the multimedia content was received and stored in flash NVM (330), i.e., the requesting process (350) may reside in another device and be connected by a network to the receiving device (310) that hosts the access process (360), and the requesting process (350) may be requesting and downloading all or selected portions of the multimedia content that is stored in the flash NVM (330) on the receiving device (310) from the access process (360) on the receiving device (310). For example, the requesting process (350) may be embedded into a high-definition television that is requesting and displaying the multimedia content that is stored on a mobile receiving device (310) and that supports the access process (360), where the network connection between the requesting process and the television may be WiFi or an ad-hoc WLAN network, or via wired Ethernet or Powerline or DSL or Cable or via other types of networks. As another example, the requesting process (350) may be hosted on a personal computer or high-end mobile multimedia device, and the multimedia content is stored on a receiving device (310) that supports the access process (360) and that is embedded within a USB dongle that is attached to the personal computer or high-end mobile multimedia device through a USB port.

If the requesting process (350) is one that supports play back of the multimedia content by a media player (370), the requesting process (350) may specify a start presentation time for play back of the multimedia content relative to the beginning of the multimedia content to the access process (360), and the access process (360) is meant to provide back to the requesting process (350) the stream of multimedia content corresponding to the specified start presentation time at a rate that generally equals or exceeds the playback rate of the multimedia content, where there is minimal time between when the requesting process (350) makes the request to the access process (360) and when the access process (360) first starts providing the stream of multimedia content to the requesting process (350). As another example, the requesting process (350) may specify a start presentation time, an end presentation time, and a rate, and the access process (360) may provide the multimedia content starting at the specified start time in a steady stream until the point in the multimedia content that corresponds to the end presentation time at the specified rate. As another example, the end presentation time may precede the start presentation time, in which case the multimedia content may be provided backwards. As other examples, the requesting process may provide a start byte position and an end byte position, and the access process (360) may provide the requested multimedia content between the specified start and end byte position to the requesting process (350). In some cases the requesting process (350) may specify a rate at which the multimedia content is to be provided, and in other cases the end byte position may precede the start byte position.

In general, the requesting process (350) may make multiple uncoordinated requests sequentially or concurrently, and there may be multiple requesting processes interfacing with the same access process (360). There may be some portions of the multimedia content that are never requested by the requesting process (350), and there may be other portions of the multimedia content that are requested multiple times, potentially in multiple non-identical requests that overlap with that portion.

An advantage of a BMSAS is that generally only data accessed is related to multimedia content that is viewed by the user, and in particular multimedia content for which data is received at the receiver device but never viewed by the user is not further processed after it is written to the flash NVM as it is received. As an example of where this is an advantage is when data for a lot of multimedia content is proactively pushed to receiver devices, in the hope that they will eventually view at least some of the multimedia content, e.g., there may be a service that continually pushes the 100 top television episodes to receiver devices, because it is very network efficient to send this data via broadcast. However, it may be the case that each user of a receiver device only views (or consumes) 5% of the multimedia content pushed to their receiver device on average (although it is likely to be different users view different percentages, and that which portions each user views is different). In this case, it would be very wasteful for each receiver device to proactively recover 100% of the multimedia content, and instead a BMSAS provides the advantage that on average only around 5% of the data written to flash NVM will be read back into the RAM and provided to the media player for play back in this case, while at the same time a BMSAS provides a very good user experience, as it enables the display of any portion of requested multimedia content shortly after it is requested.

Another advantage provided by a BMSAS is that data is written to the flash NVM only once. Taking the example provided in the previous paragraph, if all of the multimedia content were recovered and written to flash NVM before viewing, the number of writes to the flash NVM would be twice as high as when a BMSAS is used. A BMSAS can avoid writing anything to the flash NVM except for the original data received from the broadcast network.

The interface between the requesting process (350) and the access process (360) could be based on HTTP 1.1 byte range requests, i.e., the requesting process (350) provides a URL and a byte range request to the access process (360), and the access process (360) uses this to decide if it has the corresponding multimedia content referenced by the URL, and if so then uses the byte range request to determine which range of bytes from the referenced multimedia content to deliver back to the requesting process (350). Many other types of interfaces are possible as well, as one skilled in the art will recognize. The requests might also be DASH requests, which make for easy conversion between byte range requests and portions of the multimedia content. As DASH-enabled receiver could handle DASH requests in native format.

For example, the interface could be defined in terms of a Virtual Storage Device (hereafter referred to as “VSD”), which is a logical representation of a physical storage medium capable of storing and maintaining content stored on physical storage medium, such as flash NVM or other types of physical storage medium. This logical representation could be formed as part of programming of a particular device and/or the data structures used for moving data around. The physical storage medium represented by a VSD can be internal, embedded storage of a device or removable storage, either internal or external. A VSD definition, such as might be stored as program instructions or logical data structures, defines protocol methods for writing and reading content to the physical storage medium. For example, the VSD writing protocol method could be the writing portion of the methods of the receiving process (320) shown in FIG. 3, whereas the VSD reading protocol method could be the reading and decoding portions of the methods of the access process (360) shown in FIG. 3.

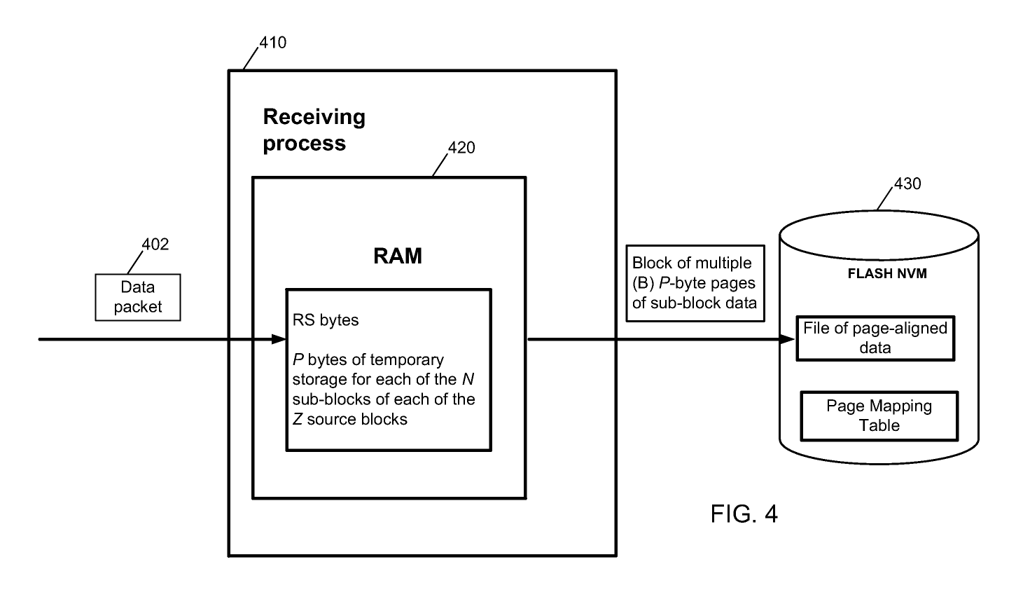

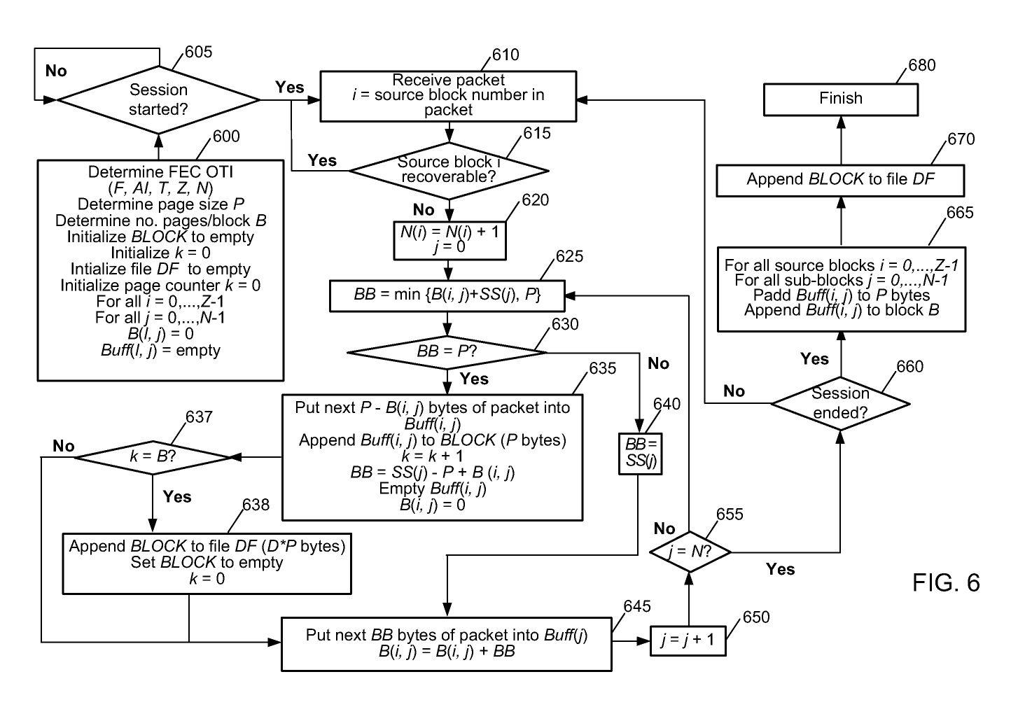

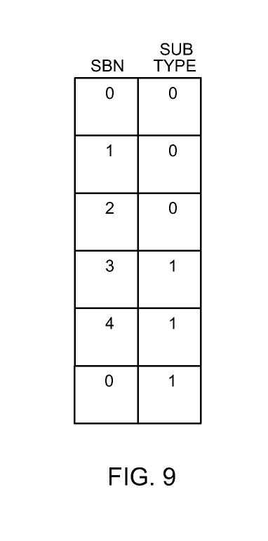

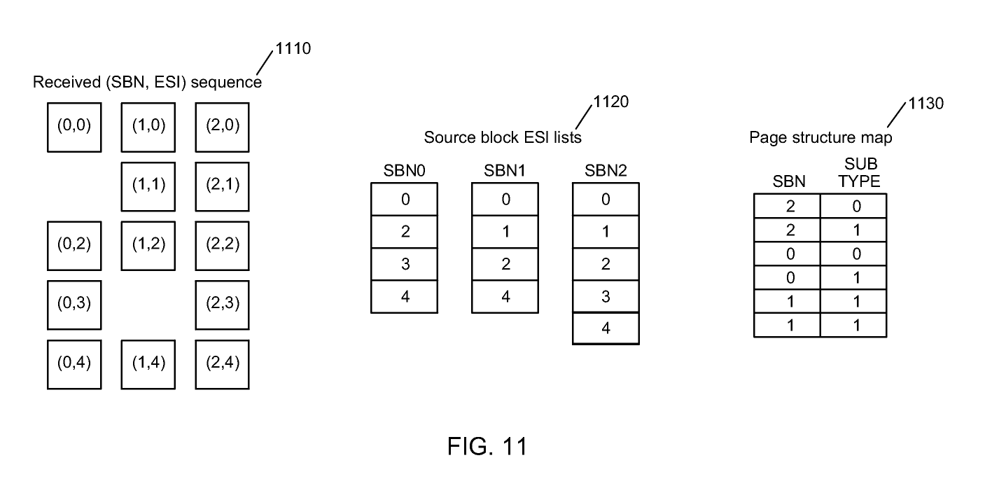

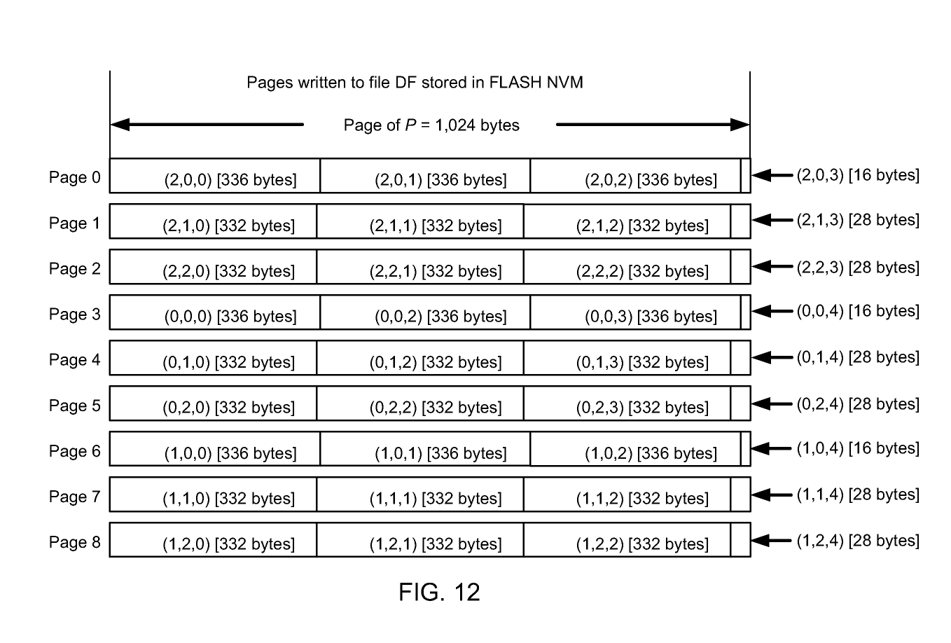

FIG. 4 shows a possible VSD writing protocol method as embodied by the receiving process (410), wherein inputs to the VSD writing protocol method comprise the FEC Object Transmission Information (hereafter referred to as the “FEC OTI”), as defined for example in [Raptor-RFC5053] or MaptorQ-RFC6330], and received data packets (402). In this embodiment, the multimedia content is partitioned into source blocks and sub-blocks at the sender based on the FEC OTI as described in [Raptor-RFC5053] or [RaptorQ-RFC6330], and the data transmitted for the multimedia content is generated and transmitted as described in [Raptor-RFC5053] or [RaptorQ-RFC6330]. Thus, the multimedia content comprises transport objects that are either source blocks (if no sub-blocking is used), or comprises transport objects that are sub-blocks of the source blocks (if sub-blocking is used, i.e., if the number, N, of sub-blocks is greater than 1). Data is generated from these transport objects and transmitted in an interleaved form as described in [Raptor-RFC5053] or [RaptorQ-RFC6330]. In this example, the physical storage medium is the flash NVM (430), and the VSD writing protocol method writes to the flash NVM (430) according to the receiving process (410) methods and procedures described below with reference to FIG. 6, FIG. 9, FIG. 11 and FIG. 12. The VSD writing protocol method creates and maintains the internal data structures and data that are used by the corresponding VSD reading protocol method, e.g., the page structure map shown in FIG. 9 and also 1130 of FIG. 11, and the source block ESI lists 1120 of FIG. 11.

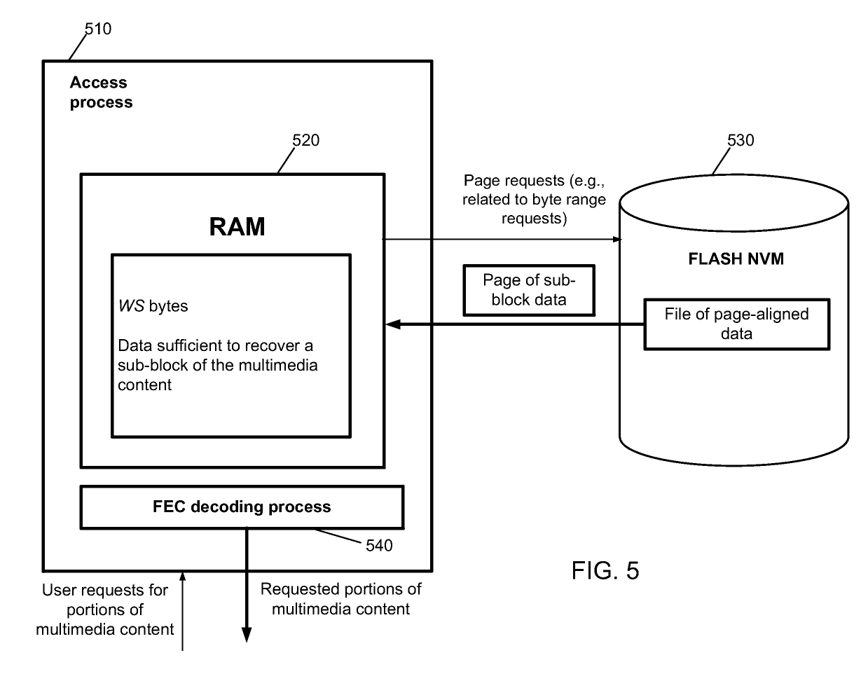

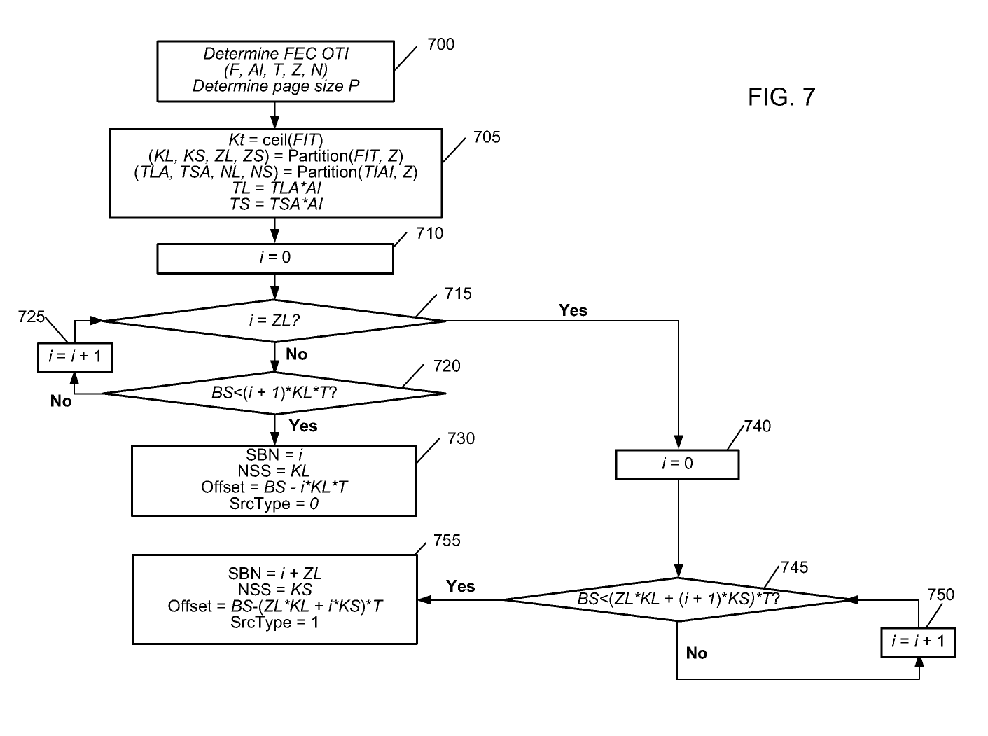

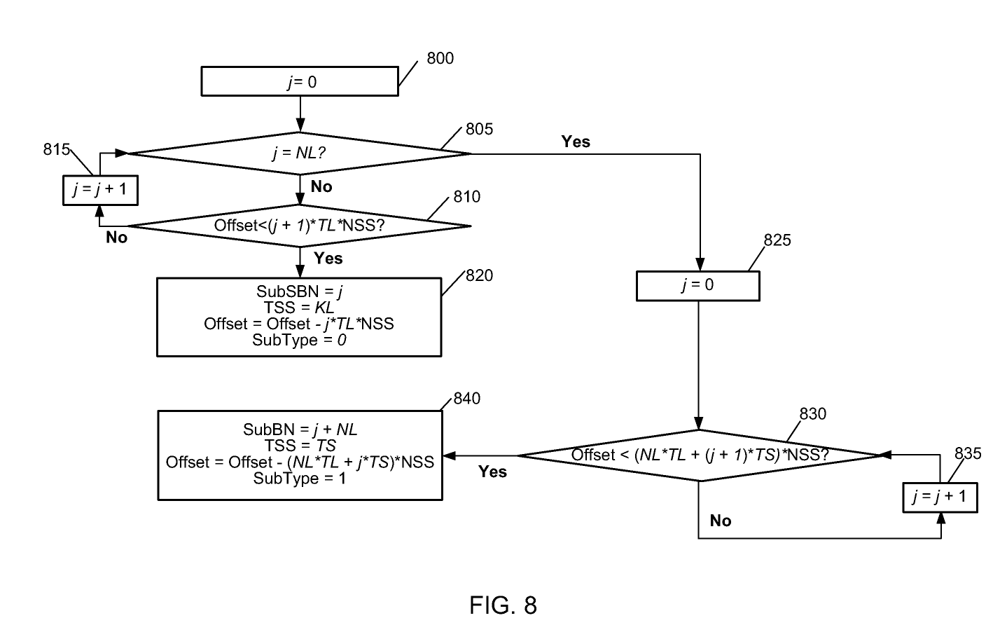

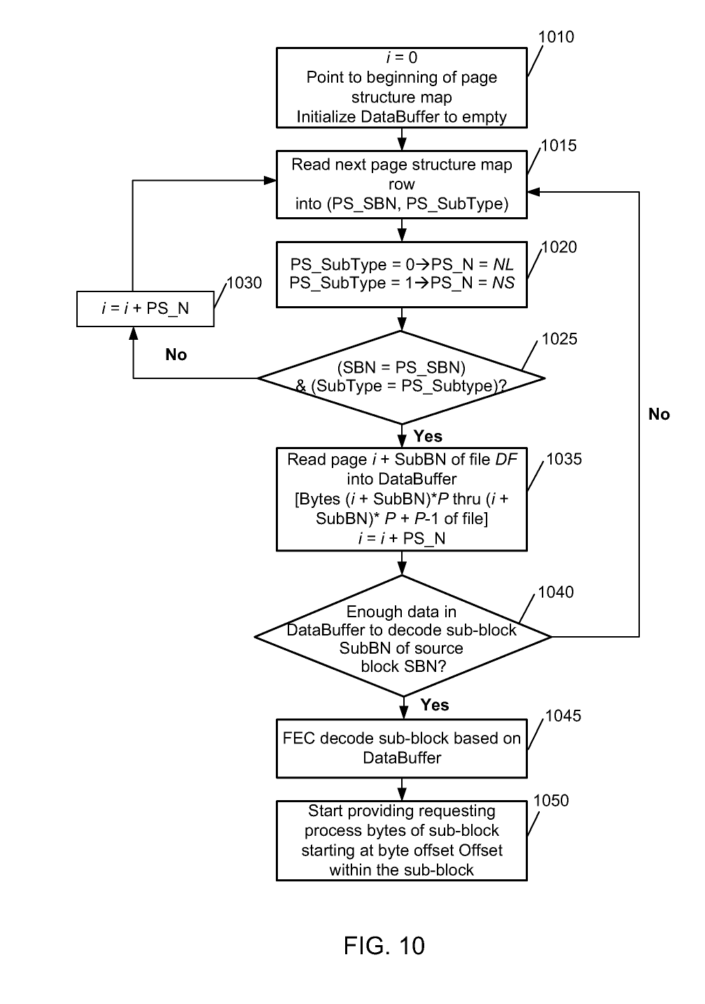

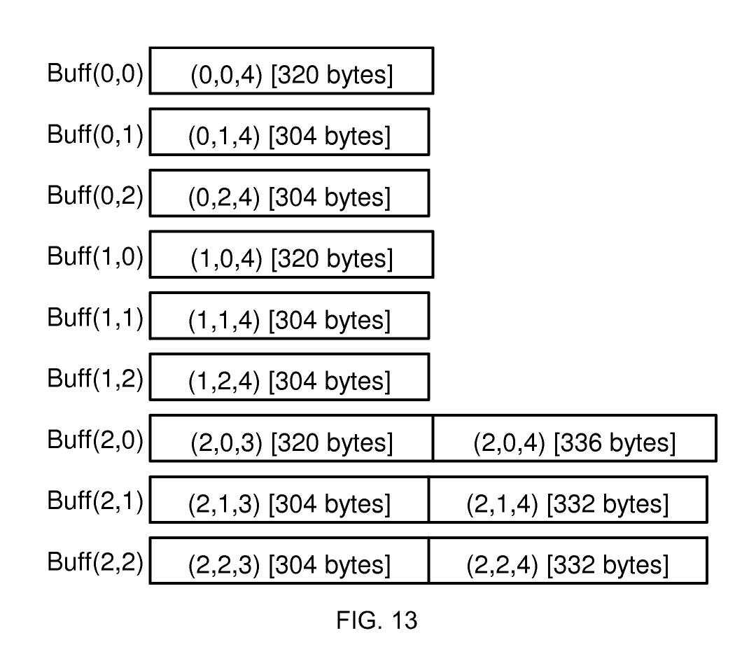

FIG. 5 shows a possible VSD reading protocol method as embodied by the access process (510), wherein inputs to the VSD reading protocol method comprises the FEC OTI and requests for portions of the content, for example in the format of an HTTP 1.1 byte range request, and the output from the VSD reading protocol method is the corresponding portion of the content referenced by the byte range. In this example, the physical storage medium is the flash NVM (530), and the VSD reading protocol method reads portions of the data related to the request byte range portion of the content from the flash NVM (530) and reconstructs from this the requested byte range portion of the content according to the access process (510) methods and procedures described below with reference to FIG. 7, FIG. 8, FIG. 10 and FIG. 13.

The VSD reading protocol method also accesses the internal data structures and data that is created by the VSD writing protocol method. The VSD reading protocol method may also create additional internal data structures such as an FEC decoding schedule that may be used to decode related sub-blocks of the encoding data for the content, wherein the sub-blocks might be related in the sense that the received pattern of encoding symbol identifiers (hereafter referred to as “ESIs”, as defined for example in [Raptor-RFC5053] or [RaptorQ-RFC6330]), received encoding data for these sub-blocks. The multimedia content may be encrypted. Preferably, the encryption is applied prior to FEC encoding of the multimedia content, and the ability to independently decrypt sub-blocks is desirable.

FIG. 4 illustrates the receiving process (410) in more detail, i.e., the receiving process (410) receives data packets (402) from the broadcast network, temporarily stores them in RAM (420) using a total of at most RS bytes, and writes the data in the received packets to the flash NVM (430) in page-aligned format. All of the steps illustrated in FIG. 4 can happen concurrently: as some of the data carried in packets arrives, other already arrived data is temporarily stored and rearranged in RAM, and other parts of the already rearranged data is written in blocks to flash NVM.

FIG. 5 illustrates the access process (510) in more detail, i.e., the access process (510) receives requests from the request process for portions of multimedia content, makes appropriate requests to the flash NVM (530) to read in portions of the data that will allow the access processor (510) to use an FEC decoding process (540) to recover the portions of the multimedia content and provides the portions of the multimedia content back to the request process. All of the steps illustrated in FIG. 5 can happen concurrently: as some of the data is read from flash NVM into RAM, other portions of data already read into RAM can be rearranged and decoded to recover portions of the multimedia content, and other portions of the already recovered multimedia content can be provided to the request process.

FIG. 6 illustrates possible logic of a receiving process method shown in FIG. 4. In Step 600 of FIG. 6, the FEC OTI parameters (F, Al, T, Z, Al) are determined, where F is the size of the multimedia content in bytes, Al is an alignment factor that is used to make sure that sub-symbols are aligned on memory boundaries that are multiples of Al, T is the size of the symbols sent in the transmission, Z is the number of source blocks into which the multimedia content is partitioned for transmission, and N is the number of sub-blocks into which each source block is partitioned for transmission. Also in Step 600, the size P of the flash NVM page is determined, the number B of pages to write each time to flash NVM is determined, and a block BLOCK of RAM is initialized to empty and the number k of pages currently stored in BLOCK is initialized to 0, where data stored in BLOCK will be written to flash NVM in one write operation, and a file DF is initialized to empty, where DF will be used for storing data in the flash NVM received for the multimedia content. Also in Step 600, B(i,j) is initialized to zero and Buff(i,j) is initialized to empty for all sub-blocks j of source blocks i, where B(i,j) is the amount of data currently stored in Buff(i,j) and Buff(i,j) is the data received for sub-block j of source block i that has not yet been written to flash NVM. In Step 605 of FIG. 6 it is determined if the session has started, and once the session has started in Step 610 a packet is received and i is set to the source block number carried in the FEC Payload ID of the received packet. (The encoding symbol ID, or “ESI”, of the received packet is also extracted and saved to the ESI list for source block i if source block i is not yet recoverable in Step 615.)

In Step 615, it is tested to see if source block i is recoverable, and if so then this packet is silently discarded and processing returns to Step 610, but if source block i is not yet recoverable then in Step 620 the number of packets N(i) received for source block i is increased by one to reflect the reception of this packet, and the sub-block index j is initialized to zero. In Step 625 the number of bytes BB that have been accumulated for writing to the next page of flash NVM for sub-block j of source block i is calculated, where SS(j) is the size of the sub-symbols of sub-block j. In Step 630 it is tested to see if the current page is full, and if so then in Step 635 the current page is appended to BLOCK and the number k of pages that BLOCK contains is incremented by 1, and BB is set to the number of bytes of sub-symbol j of source block i from the packet that was not written into the current page, and Buff(i,j) is reset to empty, B(i,j) is reset to zero, and process proceeds to Step 637. In Step 637 it is checked to see if BLOCK stores B pages, and if so then in Step 638 the B*P bytes of BLOCK are appended to file DF in flash NVM, BLOCK is reset to empty and the number of pages k that BLOCK stores is reset to 0, and processing continues on to Step 645. If BLOCK does not store B pages in Step 637 then processing continues to Step 645. If the current page is not full in Step 630 then in Step 640 the value of BB is set to the sub-symbol size SS(j) and processing proceeds to Step 645. In Step 645 the remaining BB bytes of sub-symbol j of source block i from the packet that was not written into the current page is appended to Buff(i,j) and the value of B(i,j) is increased by BB. In Step 650 the sub-symbol index j is incremented by 1, and if in Step 655 all N sub-symbols have not been processed then processing returns to Step 625 to process the next sub-symbol of the packet, but if all N sub-symbols have been processed then processing proceeds to Step 660. In Step 660 it is checked to see if the session has ended and if so then proceeds to Steps 665 to append all remaining data in Buff(i,j) for all sub-blocks and source blocks to BLOCK, in Step 670 BLOCK is appended to file DF in flash NVM and then processing finishes in Step 680. If the session has not ended in Step 660 then processing proceeds to Step 610 to receive the next packet. In Step 660, the session may be deemed to end if all source blocks of the multimedia content are recoverable.

If should be understood that the logic provided in FIG. 6 and elsewhere herein can be implemented as program instructions stored on non-transitory, computer- or device-readable memory or storage and executed by a processor or specialized hardware. It should also be understood that all of the steps need not be performed exactly as shown in the order shown.

In the description of FIG. 6, the sub-blocks can be considered to be transport objects, and the sub-blocks that comprise a source block can be considered as related transport objects, wherein the same interleaved pattern of FEC data is transmitted for the related transport objects, and the FEC data transmitted for unrelated transport objects, i.e., transport objects corresponding to sub-blocks of different source blocks, can be transmitted in an arbitrary interleaved order.

FIG. 7 illustrates possible logic of an access process method shown in FIG. 5. Based on a byte index BS, where BS is an input, some relevant source block information is determined about the first byte with index BS within the data file DF requested of the access process by the requesting process. In Step 700 the FEC OTI parameters (F, Al, T, Z, N) and the page size P is determined In Step 705 the partition of Kt=ceil(F/T) into Z source blocks is determined, resulting in ZL source blocks with KL source symbols each and ZS source blocks with KS source symbols each. Also in Step 705 the partition of T into N sub-symbols is determined, resulting in NL sub-blocks with sub-symbol size TL and NS sub-blocks with sub-symbol size TS. In Step 710 the source block index i is initialized to zero. In Step 715 it is tested if i=ZL and if so then processing proceeds to Step 740 to consider the remaining ZS source blocks, but if not then processing proceeds to Step 720 to continue considering the first ZL source blocks. Steps 720 and 725 are used to find the source block that contains the byte that starts at position BS in the multimedia content (if the source block is among the first ZL). If BS is found to be among the first ZL source blocks, then in Step 730 the value of SBN is set to the source block i, the value of NSS is set to the number KL of source symbols in source block i, the value of Offset is set to the position of BS relative to the beginning of source block i, and the value of SrcType is set to zero to indicate that the source block was among the first ZL. Steps 740, 745, 750 and 755 are similarly used to determine the source block number SBN, number of source symbols NSS, offset Offset of BS relative to the beginning of the source block in the case that BS is among the last ZS source blocks, where in this case SrcType is set to one to indicate that the source block was among the last ZS.

FIG. 8 illustrates possible logic of an access process method shown in FIG. 5 related to determining some relevant sub-block information about the first byte BS requested of the access process by the requesting process within the data file DF, and is similar to FIG. 7. The inputs to FIG. 8 are the outputs from FIG. 7, i.e., SBN, NSS and Offset are inputs to FIG. 8, wherein SBN is the source block number wherein the byte with index BS within DF is contained, NSS is the number of source symbols of the source block SBN, and Offset is the offset into source block SBN of the byte with index BS within DF. The logic shown in FIG. 8 is used to determine the sub-block index SubBN of the sub-block in which the byte with index Offset within source block SBN is contained, the number of sub-symbols TSS of sub-block SubBN, recalculates Offset to be the Offset within sub-block SubBN of the byte with index BS within DF, and determines the SubType of sub-block SubBN, wherein SubType=0 if sub-block SubBN is one of the first NL sub-blocks of source block SBN and otherwise SubType=1.

FIG. 9 illustrates an example of a possible page structure map that can be generated by the receiving process (410) of FIG. 4. A page structure map is one possible succinct description of how the data that is written to the data file DF stored in flash NVM by the receiving process (410) is related to the source block and sub-block structure of the multimedia content. In this example of a page structure map, each row contains a SBN and a SubType, where the SBN is the source block number of a source block and SubType has the meaning as described in FIG. 8. The interpretation of the page structure map can be understood with reference to FIG. 10, which describes an access process for reading data for a sub-block from flash NVM.

FIG. 10 illustrates possible logic of an access process reading into RAM the data pages for the sub-block that contains the byte BS of the multimedia content within the data file DF, decoding the sub-block from the data pages, and initiating providing the multimedia content to the requesting process starting at byte BS. The input SBN to FIG. 10 is generated from FIG. 7, and the input SubType to FIG. 10 is generated from FIG. 8 based on BS. In Step 1010, the page number i is initialized to zero, the process starts at the beginning of the page structure map (in the format shown in FIG. 9), and the DataBuffer that is used to store data read in from the data file DF stored in flash NVM to RAM is initialized to empty. In Step 1015 the next row of the page structure map is read into (PS_SBN, PS_SubType), which indicates that the next set of pages within DF contain data for source block PS_SBN, and PS_SubType is used to determine the number of such pages. In Step 1020 the PS_SubType is used to determine PS_N, where there is one page of data in the set for each of PS_N sub-blocks. In Step 1025 it is tested to see if SBN is equal to PS_SBN and SubType=PS_SubType, where SBN is determined by the process described in FIG. 7 and SubType is determined by the process described in FIG. 8. If the test of Step 1025 is false, then this means that none of the next PS_N pages in DF contains data for sub-block SubBN of source block SBN, where SubBN is determined by the process described in FIG. 8, and then these next PS_N pages are skipped over in Step 1030. If the test of Step 1025 is true, then this means that there is one page of the next PS_N pages that contains data for sub-block SubBN of source block SBN, and then this page is identified and read into the DataBuffer from the data file DF in Step 1035, and the remainder of the PS_N−1 pages are skipped over. In Step 1040 it is checked if there is enough data in DataBuffer to decode the sub-block, and if not then processing goes back to Step 1015 to read in more pages, but if so then processing proceeds to Step 1045 to use an FEC decoding process to decode the sub-block. During the FEC decoding process of Step 1045, the corresponding list of ESIs for received symbols of the source block of which this sub-block is part can be used to determine the schedule of decoding operations to recover the sub-block, where an example of such an ESI list is shown in 1120 of FIG. 11. In Step 1050 the multimedia content of sub-block SubBN of source block SBN, starting at position Offset within the sub-block, is provided to the requesting process. Note that position Offset within sub-block SubBN of source block SBN corresponds to position BS within the multimedia content, where Offset is one of the outputs of FIG. 8.

As an example of a BMSAS in operation, suppose for a multimedia content that the FEC OTI is F=370,000 bytes, Al=4 bytes, T=1,000 bytes, Z=3, N=3. Then, the multimedia content has 370 source symbols, and is partitioned into three source blocks with 124, 123, 123 source symbols each, respectively, and each symbol is partitioned into three sub-symbols of size 336, 332, 332 bytes each, respectively. FIG. 11, FIG. 12 and FIG. 13 show an example of receiving some data packets and the corresponding data structures that are generated as these data packets are received. Diagram 1110 of FIG. 11 shows an example of data packets being received, where the pair of numbers shown within each data packet indicate the SBN and ESI of the symbol carried in the data packet, and the reception is across the rows and from top to bottom. In this example, data packets (0,1) and (1,3) are not received by this receiver. Diagram 1120 shows the corresponding list of received ESIs for each of the 3 source blocks, in the order that they were received. Diagram 1130 shows the corresponding page structure map that has been built up so far based on these received packets, which can be understood in more detail by reference to FIG. 12 and FIG. 13.

FIG. 12 illustrates the pages that have been either written to the data file DF stored in flash NVM by the receiving process, or stored in BLOCK for writing as a block to the data file DF at some subsequent time, after having received the packets shown in diagram 1110 of FIG. 11. In FIG. 12 the triple (SBN, SubBN, ESI) is used to indicate which sub-symbols are contained in each page, and the number of bytes of each sub-symbol contained within the page is also shown. Note that each page contains information about sub-symbols related to one (SBN, SubBN) pair, but may contain more than one such sub-symbol and may split a sub-symbol over more than one page. For example, in Page 0, all of the data is for source block 2 and sub-block 0, and the first three sub-symbols of size 336 bytes with ESIs 0, 1, 2 fit completely within Page 0, but only 16 bytes of the sub-symbol with ESI 3 fits in Page 0 and the remainder of this sub-symbol will be at the beginning of a later page. In general there are two different types of sub-blocks for each source block, there are NL sub-blocks of SubType=0 with the larger sub-symbol size TL, and there are NS sub-blocks with the SubType=1 with the smaller sub-symbol size TS, and these two different types have a different pattern of fitting into pages. However, if there are PS_N sub-blocks of the same SubType for a source block, then the layout of the pages for these sub-blocks will always be consecutive groups of PS_N pages. This explains why the page structure map has the suggested form, e.g., the form shown in FIG. 9 and also in 1130 of FIG. 11. Many other forms or organizations for the page structure map or its equivalent are possible.

FIG. 13 illustrates the portions of the received data that have not yet been either written to the data file DF stored in flash NVM, or not yet stored in BLOCK for writing as a block to the data file DF at some subsequent time, by the receiving process after having received the packets shown in diagram 1110 of FIG. 11. This is the remainder of the data that has been received but is not shown in FIG. 12. Note that there is one buffer for each sub-block of each source block, but other possible organizations of buffers are also possible, including having one buffer for all data received but not yet written to file DF, or BLOCK, or one buffer per source block and sub-block type.

Suppose multimedia content size is F bytes, and the maximum block size that is desired to be used by the receiving process is RS bytes, and the maximum block size that is desired to be used by the access process is WS bytes, and the flash NVM page size is P bytes. Basic desirable condition when the methods are most advantageous: F is at most RS*WS/P. For example, if RS=1 MB and WS=1 MB and P=1,024 bytes, then the most efficiency is gained if F is at most 1 GB. However, the methods and processes described herein are still advantageous when these conditions are not met, as described in more detail below.

In some contexts, the values of RS and WS are very important because the amount of available RAM at the receiver is a constrained resource. In these contexts, the values of RS and WS may be set equal to one another in order to minimize the maximum block size needed in RAM while any of the processes of the system are running, or it may be the case for example that RS is allowed to be some multiple of WS, for example RS=4*WS, if for example the amount of RAM available when the receive process is running is more than the amount of RAM available when the recovery or access processes are running, or if for example the amount of RAM used for the receive process as a function of RS is smaller than the amount of RAM used for the recovery or access processes as a function of WS.

In other contexts, the value of WS needs to be minimized to increase the access speed to the multimedia content provided by the access process. For example, setting WS=256 KB allows the access process to read at most 256 KB from the flash NVM before being able to process and provide the first portion of multimedia content to the requesting process. In this context, the value of RS might be set by the receiver based on the given values of F, P, and WS, i.e., RS is set to at least F*P/WS. For example, if F=100 MB and WS=256 KB and P=4,096 bytes then RS can be set to 1,600 KB. In general, the values of WS and RS may not be explicitly set at the receiver, but instead may be implicit. For example, in [RaptorQ-RFC6330], the FEC OTI information (F, Al, T, Z, N) determines the value of WS implicitly, where Al is an alignment factor (typically set to 4), T is the symbol size, Z is the number of source blocks into which the F bytes of the multimedia content are partitioned, and N is the number of sub-blocks into which each source block is partitioned. The value of RS might also be implicitly defined. For example, the value of RS might be derived as approximately equal to P*Z*N.

There are also advantages if F is greater than RS*WS/P. For example, if F =2*RS*WS/P, then each read from the flash NVM is for half of a page, which is generally still fairly efficient, although not quite as efficient are reading a full page each time. In general, many of the advantages of a BMSAS can be achieved even if each page of flash NVM is filled with a mix of data from different sub-blocks or source blocks, and if the data for sub-blocks and/or source blocks is not organized according to page-aligned boundaries in flash NVM. For example, it could be that when the received data is written into one or more files stored in flash NVM that the chunk sizes of data written for a particular sub-block are either not a multiple of a page size or not written starting at a page-aligned byte index within flash NVM. Nevertheless, if the chunks of data read in from flash NVM for decoding a particular sub-block and/or source block are a significant fraction of the flash NVM page size then the time to read in all of the data used to decode a sub-block or source block can still be reasonably close to the time it would take to read in all of the data if it were stored page-aligned in flash NVM.

As another example, the multimedia content might be partitioned into more than one multimedia content, and the data for the first multimedia content is transmitted before the data for the second multimedia content, wherein each multimedia content is of size at most RS*WS/P.

Consider a BMSAS in operation with the following example parameters: F=100 MB, P=2,048 bytes, T=1,200 bytes. Suppose that it is desired that WS≦256 KB. Using the FEC OTI derivation algorithm specified in [RaptorQ-RFC6330] based on a maximum sub-block size of 256 KB, the file is partitioned into Z=13 source blocks: 9 source blocks with 6,722 source symbols and 4 source blocks with 6,721 source symbols. There are N=34 sub-blocks per source block: 28 sub-blocks with sub-symbol size 36 bytes and 6 sub-blocks with sub-symbol size 32 bytes. In this example, the maximum sub-block size turns out to be 6,722*36=241,992 bytes, which is less than WS. Also, the value of RS can be approximately Z*N*P=13*34*2,048=905,216 bytes.

When the BMSAS operates with the above example parameters, once the received data from the broadcast is stored in the flash NVM, the time it takes the access process (360) to provide the initial response to any request from the request process (350) is the amount of time it takes to read in from the flash NVM (330) one sub-block of page-aligned data and FEC decode the sub-block, i.e., around 256 KB of data. Supposing that the rate that pages of data from the flash NVM (330) can be read into RAM is 30 Mbps. In this case, it takes around 70 ms for the access process (360) to read in the data for one sub-block, and typically it would take the access process (360) a small amount of additional time (depending on the processor used by the access process) to decode and present the multimedia content of the sub-block to the request process (350) if the BMSAS uses the FEC code and sub-blocking described in [RaptorQ-RFC6330], and thus for example the total time could be less than 100 milliseconds between when the request process (350) requested a portion of multimedia content and when the access process (360) started feeding the requested multimedia content to the request process (350).

In contrast, suppose that the BMSAS methods disclosed herein were not used, but instead known techniques, such as those disclosed in [LDPC-RFC5170], were used. To have anywhere near the network efficiency of the example described above, a very large source block size would be needed, e.g., 12 MB source blocks (and even then the network efficiency could be 20% or more worse than the network efficiency provide by using the BMSAS and [RaptorQ-RFC6330] as described above). In this case, the at least 100 MB of data received for the multimedia content would be stored in flash NVM, then the data would be read back into RAM from the flash NVM, decoded in RAM, and stored back to flash NVM from RAM. At 30 Mbps for the flash NVM read access speed, and at 4 Mbps for the flash NVM write access speed, the steps of reading the stored data from the flash NVM into RAM, decoding, and writing the recovered multimedia content back to the flash NVM from RAM would take at least two and a half minutes, which provides several minutes slower access to the multimedia content by the receiver than is provided by in the BMSAS example above with the same input parameters. Furthermore, the [LDPC-RFC5170] solution uses receiver device resources during recovery of the multimedia content that could be wasteful if the multimedia content is never viewed or consumed at the receiver once the data for the multimedia content is received. Furthermore, the amount of RAM needed for decoding would be at least 12 MB.

If instead some of the BMSAS methods and processes described herein are applied directly to the file delivery solution in [LDPC-RFC5170] using 12 MB source blocks (but not using sub-blocking), then each access to a portion of the multimedia content would involve reading in at least 12 MB of data for a source block, then decoding it, and then supplying the recovered multimedia content to the media player. Thus, each such access would take more than 3 seconds, i.e. more than an order of magnitude slower than the access time for BMSAS example described above that uses the FEC code and sub-blocking described in [RaptorQ-RFC6330]. Thus, the combination of the BMSAS methods described herein and the methods described in [LDPC-RFC5170] provides benefits, but, in some cases, the combination of [RaptorQ-RFC6330] and the BMSAS methods described herein provide more benefit.

In some variants of a BMSAS, it is desirable to store much more data on flash NVM than needed to recover parts of the multimedia content, e.g., much more FEC encoding stored than actually needed to recover the multimedia content. If parts of the flash NVM become unavailable or corrupted, the multimedia content may still be able to be recovered from other portions of the stored data that is still available.

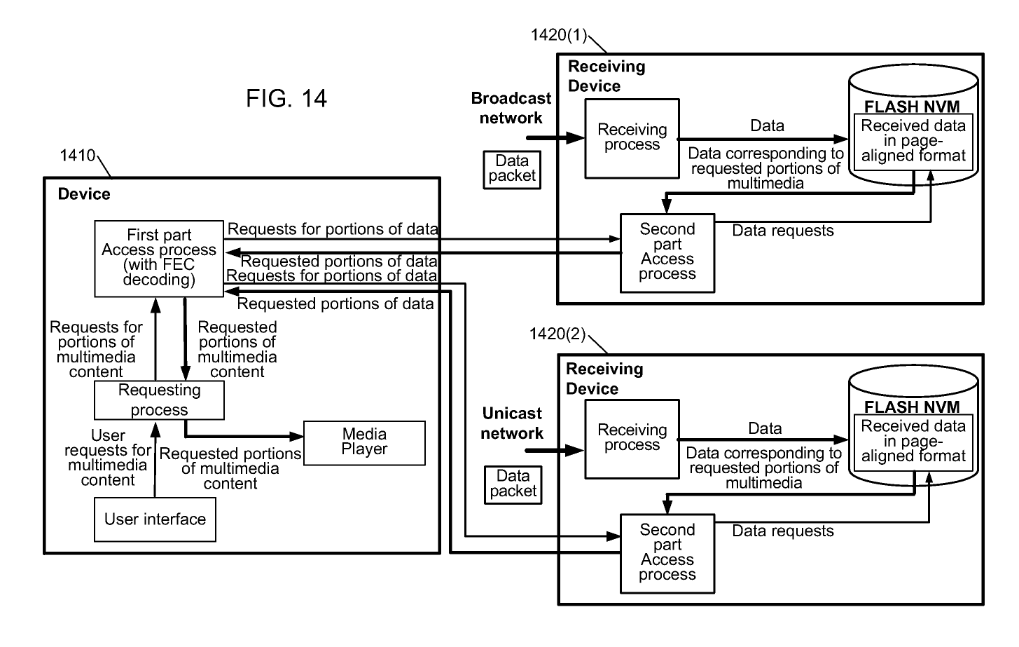

In some variants of a BMSAS, it may be desirable to store portions of the data in different flash NVMs in different receiver devices. In this case, the functionality of the access process may be split across different devices. The requesting process may be on a device that is not the same as either of two receiver devices that have portions of data stored in flash NVM, in which case the requesting device requests portions of the data from a first part of an access process that is on the same device as the requesting device, and then the first part of the access process requests data for the multimedia content from the second parts of the access processes on the devices which store the data for the multimedia content in flash NVMs, and then the first part of the access process takes the data received from multiple second parts of the access process and performs FEC decoding to recover the appropriate portions of the multimedia content and provide it to the requesting process. An example of such a variant is illustrated in FIG. 14, where there is a device upon which the multimedia content is to be consumed or viewed (1410), and receiving devices (1420 (1), 1420 (2)). In some cases, the receiving devices receive broadcast packets and others receive unicast packets. In some cases, a receiving device might receive some of both.

As described, the number of files used to store received data in flash NVM can be independent of the number of source blocks and the number of sub-blocks, i.e., all received data for all source blocks can be written to the same file in flash NVM. Alternatively, there could be a different file for storing the data of each source block, assuming the file system has the capacity to write to multiple files either concurrently or in an alternating way as data for the source blocks is received. Similarly, the information that identifies which symbols and sub-symbols were received, i.e., the source block number, sub-block number, and encoded symbol identifier, either explicitly or implicitly could be written in a separate file(s), or stored in the same file(s) as the received data.

There are other possible alternatives for implementing a BMSAS or BFDS. For some AL-FEC codes, sub-blocking is either not available or not desired to be used, and thus objects or files or multimedia content is partitioned and encoded as source blocks without the usage of sub-blocking. For example, the AL-FEC codes specified in [LDPC-RFC5170] do not incorporate sub-blocking, although these AL-FEC codes could be extended to incorporate sub-blocking. When sub-blocking is not used, there are still advantages to applying the methods and techniques described herein. For example, as a first alternative, if each source block can fit into and be decoded in RAM then the methods and techniques can be applied directly, using source blocks and symbols instead of sub-blocks and sub-symbols. This alternative has many of the same benefits of the methods and processes described previously, with the possible exception of the preferred trade-off between network efficiency and the amount of RAM needed at a receiver device for recovering and presenting the object, file, or multimedia content.

Even in the case that source blocks are too large to be decoded in RAM directly, there are other ways to provide some benefits using the techniques and methods described herein. For example, a second alternative is to use a receiving process analogous to the receiving process (320) shown in FIG. 3, the receiving process shown in FIG. 4, and the process described with reference to FIG. 6, but using source blocks and symbols in place of sub-blocks and sub-symbols. An access process analogous to the access process (360) shown in FIG. 3 can be used with a different requesting process, wherein the requesting process invokes the FEC decoding process and requests the symbols it needs to have stored in RAM to recover the next symbol to be recovered. This second alternative, explained in the context of, but not limited to, when the AL-FEC code described in [LDPC-RFC5170] is being used, and belief-propagation decoding is being used, could work as follows. As each symbol is recovered using the belief-propagation algorithm, the requesting process would request from the access process the values of the set of symbols upon which the next symbol to be recovered depends, so that the next symbol to be recovered can be recovered from the XOR of the symbols in the set. As symbols are recovered, the requesting process could write these recovered symbols to flash NVM in blocks in the order that they are recovered, and at the same time provide the information to the access process about the mapping between the (SBN, ESI) information for these symbols and where they are written to in the flash NVM, using a mapping format that is possibly similar to that shown in FIG. 11. After all of the source symbols are recovered (and possibly other symbols are also recovered along the way), the source block is recovered, but the source symbols are stored in flash NVM in an order that is determined by the order of their recovery, which is likely to be quite different than the order of the source symbols within the multimedia content, original object, or original file. The source symbols can be accessed in the order they appear in the multimedia content, original object, or original file, using a modified version of the access process that does not include FEC decoding but does involve using a map to access and read in from flash NVM the requested source symbols in the order they appear in the multimedia content, original object, or original file.

Note that some of the BMSAS writes and reads do not involve FEC decoding in some steps of this second alternative. For example, the writing of the recovered source symbols to flash NVM is an example of the data writing process of a BMSAS receiver method that does not involve writing FEC encoded data, and the corresponding read access of these recovered source symbols in consecutive order from the flash NVM is an example of a BMSAS access method that does not involve either reading FEC encoded data or FEC decoding.

As a third alternative, after the second alternative BMSAS process is completed, another round of using a request process to request the recovered source symbols in the order they appear in the multimedia content, original object, or original file, and then using an access process, that in turn uses a mapping generated by the second alternative BMSAS process to access the requested source symbols, and the request process writes the source symbols to flash NVM in a file in the order they appear in the multimedia content, original file, or original object.

In summary, in the context of not using sub-blocking, the first alternative has many benefits of the BMSAS processes described previously except for possibly the trade-off between the network efficiency and the RAM needed at the decoding device is less desirable than for the preferred BMSAS processes that use sub-blocking described previously. The second alternative has some of the benefits of the preferred BMSAS processes that use sub-blocking described previously, except that the request pattern depends on the FEC decoding algorithm and there is an additional read to and write from flash NVM of an amount of data that is proportional to the size of the multimedia content, original object, or original file compared to the preferred BMSAS solutions that use sub-blocking. The third alternative has some of the benefits of the preferred BFDS solutions that use sub-blocking described previously, except that the request pattern depends on the FEC decoding algorithm and there is an additional read to and write from flash NVM of an amount of data that is proportional to the size of the multimedia content, original object, or original file compared to the preferred BFDS solutions that use sub-blocking described previously.

In many of the examples detailed above, it is assumed that there is FEC data included in the stream. However, that is not required. In some implementations, interleaving is provided and error correction is handled in some other way. In some cases, the receivers might be able to work acceptably well with some losses.

In some implementations, interleaving is a consequence or side-effect of other design details. For example, suppose that the receiver is receiving multiple portions of an object or multiple objects in parallel. This might be the case, for example, where the receiver is a client in a peer-to-peer network configuration where transmitters are limited to transmit rates significantly lower than the download rate of the client.

For example, where a client can receive a download at a 5 megabits/sec rate, but peers can only upload at 256 kilobit/sec, the client might opt to connect to 20 peers so that, even when the peers are only sending at 256 kilobit/sec, the receiver can receive 5 megabits/sec. In such a case, the input to the receiver would be inherently interleaved, i.e., the receiver would be receiving interleaved data for 20 different transport objects from 20 different peers.

This interleaved data could be buffered into RAM and then have a large block of data written from the buffer RAM into flash memory as 20 transport objects (each one representing the data received from one of the peers) and the page map updated to reflect those newly written 20 transport objects. In this case, if the data from the peers were obtained using HTTP, it might be that the data is reliably received and no FEC is needed, resulting in a case where there is interleaving, but no FEC and possibly all of the errors being fixed via the underlying protocol.

In other examples, other rates, upload limits and number of simultaneous peers might have other values. In a typical case, the interleaving is high enough and the amount of memory that is available is low enough that more straightforward approaches, such as reordering in memory or using a file handle for each object, would be impractical. That said, nothing here should be construed as assuming that the clients and systems could not handle more simpler cases. For example, it might be that nothing needs to be done differently for the case where there is only one transport object being transmitted at a time (without interleaving).

In interleaved example will now be described in further detail. Consider, for example, a case where the typical multimedia content object is F=100 MB, the multimedia content object is interleaved using the parameters Z=13, Al=4, N=34, and T=1,200 bytes. The transmitter (or some logic prior to the transmission process) would pad the 100 MB multimedia content object with 800 bytes of zeroes, resulting in (100*1,048,576)+800=104,858,400 bytes, which divides evenly into K=87,382 source symbols of T=1,200 bytes each. Each of those K source symbols is then divided into N=34 source sub-symbols. Since 34 doesn't divide 1,200 evenly—1,200/34 is around 35.3—each source symbol can be divided into sub-symbols of 36 bytes each or 32 bytes each, in order to comply with the alignment factor Al=4 bytes and so that they are nearly equal and can sum to 1,200. In this instance, if each source symbol is divided into 28 sub-symbols of 36 bytes each and 6 sub-symbols of 32 bytes each, that meets the requirements of having the sub-symbols not vary in size by more than the alignment factor and having the aggregate size of all N of the sub-symbols equal to the source symbol size, T (i.e., 28*36+6*32=1,200).

The transmitter arranges those 104,858,400 bytes (87,382 source symbols) into Z=13 source blocks. Since 13 does not divide 87,382 evenly, the transmitter creates (or logically assigns) 6,722 source symbols each to nine source blocks and 6,721 source symbols each to the other four source blocks. The transmitter then creates sub-blocks from the sub-symbols, for each source block. For example, for one of the first 9 source blocks (the ones with 6,722 source symbols of 1,200 bytes each), the transmitter creates (physically or logically) sub-blocks of 6,722 sub-symbols of 36 or 32 bytes each. Specifically, for the nine 6,722 source symbol blocks, the transmitter creates 28 sub-blocks each having 6,722 sub-symbols of 36 bytes (sub-block size: 241,992 bytes) and 6 sub-blocks each having 6,722 sub-symbols of 32 bytes (sub-block size: 215,104 bytes), and for the four 6,721 source symbol blocks, the transmitter creates 28 sub-blocks each having 6,721 sub-symbols of 36 bytes (sub-block size: 241,956 bytes) and 6 sub-blocks each having 6,721 sub-symbols of 32 bytes (sub-block size: 215,072 bytes). Thus, the maximum sub-block size is 241,992 bytes. Note that this is smaller than the size (in bytes) of the source blocks, which are 6,722*1,200=8,066,400 bytes or 6,721*1,200=8,065,200 bytes.

Suppose the transmitter interleaves the data and puts it into packets, with each packet having 1,200 bytes. (The number of source symbols per packet need not be exactly one-to-one.) The interleaving might be such that one packet includes sub-symbols from many different sub-blocks or source blocks. The transmitter might or might not include forward error correction into the multimedia content object. The transmitter then transmits those packets and some of them might be lost, but the rest are correctly received by a receiver, such as the receivers described above.

Suppose the receiver has approximately RS=1 MB of RAM available to hold received data before writing it to flash memory. Even with interleaving, the receiver should be able to store some received data to do some de-interleaving, such as by grouping the received bytes into pages of contiguous bytes from specific sub-blocks. Suppose that the flash memory has a page size, P, of 2 KB (i.e., data is read from the flash memory typically in 2 KB chunks) and a block size, B, of 256 KB (i.e., flash memory is erased and written to in 256 KB chunks). The receiver could then accumulate in RAM received bytes for each of the N sub-blocks of each of the Z source blocks until the receiver has a full page's worth of bytes for one or more sub-block. This might require around Z*N*P=13*34*2,048=905,216 bytes of working memory, which is workable if the receiver has 1 MB of RAM available. Note that while the working memory of the receiving process is filling up, once one full page is available for one sub-block, it is likely that other sub-block pages are also filling up. The receiver can write out 128 complete pages (128=B/P=256/2) of data at a time to flash memory in one flash memory write operation as soon as 128 complete pages are filled with data received for the sub-blocks, and then reuse the space that was used in RAM to store these written pages to store additional received data as it arrives.

There are many alternate methods a receiver may use. As one possible alternative, the receiver may write all of the current set of complete pages as soon as the number of complete pages reaches a fixed threshold value, such as 128. As another alternative, the threshold value may depend on the FEC OTI parameters.

The receiver's receiving process also updates a page structure map indicating which sub-blocks, source blocks and ranges where written to where in the flash memory. The page structure map might be stored on the flash memory as well. When the user uses a user interface associated with the receiver to request a portion of the multimedia content object (from the start, or middle of the stream), a requesting process might convert the user's request (e.g., “Start playing out object DF starting 3:00 from the beginning”) into a byte range request, which can then be converted into sub-block requests or the like. The requesting process then passes that request to the access process, which may do the byte range to sub-block request (if not already done by the requesting process) and then uses the page structure map to determine which pages of flash memory to request. Since the data was de-interleaved (at least partly) prior to storing into flash memory, and since data is stored in a file containing many pages, rather than one page per file, there are fewer file handles needed to get at the data.

The access process obtains the data determined by the requests received from the requesting process from the flash memory, FEC decodes the data if it is FEC encoded, and provides it to the requesting process. If FEC is involved, the access process performs FEC decoding. If not, and there are some losses, the access process might just pass on the available data to the requesting process as is. The requesting process can then send the data to a media player. The effect from the user's perspective is that a request is made of the receiver and the player plays it out, with satisfactory response time. This is done within the structures explained herein which require fewer open file handles, less working memory, and faster response times from flash memory (or other NVM) as compared with other approaches.

As explained herein, data is received in interleaved form and rather than store it in fully interleaved form (which may delay processing the data when it is requested), or use a file system to fully de-interleave the data into separate files (which may require too many file handles), or de-interleave the data entirely upon receipt (which may require too much working memory, adding to device cost), the data is partially de-interleaved by the receiving process as it is written to storage and the remainder of the de-interleaving is performed by the access process as it is read in from storage. The split of the de-interleaving process between writing to storage and reading from storage takes advantage of the asymmetric nature of the storage used. A page map is provided so that portions of stored data objects can be retrieved from the storage even though they are not entirely organized in the storage as separated objects. Each page of storage can be associated with one or two objects, so that retrieval is efficient.

Where the data is interleaved according to an FEC OTI process, some of the FEC OTI information might be retained in the storage. Where FEC data is included, that might be used in a decoding stage when the stored data is actually requested. Where DASH metadata is used, it might be stored with the file's data or stored separately to allow for a process to easily read that data without a lot of decoding. It should be understood that the particular data that is interleaved need not be related, i.e., unrelated or related transport objects can be interleaved.

Where network losses are bursty losses, interleaving spreads the losses over many sub-blocks and where FEC is used to recover from that loss, some other method is used to recover from that loss (e.g., retransmission), or the loss is acceptable to the end application (e.g., the user will accept some small video artifacts caused by lack of data), then interleaving is useful. Where the appropriate sub-block size is used, partial de-interleaving can be performed with a reasonable amount of working memory.

It is to be understood that the various functional blocks in the above described figures may be implemented by a combination of hardware and/or software, and that in specific implementations some or all of the functionality of some of the blocks may be combined. Similarly, it is also to be understood that the various methods described herein may be implemented by a combination of hardware and/or software.

The above description is illustrative and not restrictive. Many variations of the invention will become apparent to those of skill in the art upon review of this disclosure. The scope of the invention should, therefore, be determined not with reference to the above description, but instead should be determined with reference to the appended claims along with their full scope of equivalents.

What is claimed is:

1. A receiving device for storing and accessing data transmitted from a source to the receiving device over a communications channel, the data generated from a plurality of transport objects using a forward error correction code and transmitted as data packets, the receiving device comprising:
a physical storage medium configured to store received data in page format;
a receiving module communicatively coupled to an input of the receiving device and to the physical storage medium, the receiving module having a first access memory and further being configured to receive the received data as data packets, store the received data in the first access memory according to a page format, write the received data formatted in page format sequentially to a file in the physical storage medium communicatively coupled to the receiving module, and generate a page structure map describing a relationship between the received data written to the file and the plurality of transport objects; and
an access module having a second access memory and being communicatively coupled to an application module and to the physical storage medium, the access module further configured to receive a request for a portion of the transport objects from the application module, determine from the page structure map which of the pages of the file include corresponding data corresponding to the requested portion of the transport objects, read the determined pages from the physical storage medium into the second access memory, and decode the corresponding data using the forward error correction code to recover the requested portion of the transport objects and provide the requested portion of the transport objects to the application module.

2. The receiving device of claim 1, wherein the physical storage medium is configured such that writes of multiple pages of data to non-sequential locations requires more time than reads of an equal number of pages of data from non-sequential locations and writing multiple pages of data to sequential locations is faster by at least a factor of two than writing an equal number of pages of data to non-sequential locations.

3. The receiving device of claim 1, wherein reception of encoding data generated from different transport objects is interleaved.

4. The receiving device of claim 3, wherein the data in each page written to the physical storage medium is encoding data generated from the same transport object.

5. The receiving device of claim 3, wherein at least a portion of the requested portion of the transport objects corresponds to at least part of one transport object and encoding data generated from that transport object is stored in at least a portion of the determined pages read from the physical storage medium into the second access memory.

6. The receiving device of claim 1, wherein the aggregate amount of data in the determined pages read from the physical storage medium into the second access memory to recover a requested portion of the transport objects is roughly the size of the requested portion of the transport objects.

7. The receiving device of claim 1, wherein at least some of the plurality of transport objects comprise related multimedia content.

8. The receiving device of claim 7, wherein the requested portion of the transport objects comprising the multimedia content is provided to the application module at approximately a playout rate of the multimedia content.

9. The receiving device of claim 1, wherein at least some of the plurality of transport objects comprise unrelated content.

10. The receiving device of claim 1, wherein the size of the first access memory is smaller than the size of the plurality of transport objects and wherein the size of the second access memory is smaller than the size of the plurality of transport objects.

11. A method for storing and accessing data transmitted from a source to a destination over a communications channel, the data generated from a plurality of transport objects using a forward error correction code and transmitted as data packets, the method comprising:
receiving the received data as data packets;
storing the received data in a first access memory according to a page format;
writing the received data formatted in the page format from the first access memory to a file in a physical storage medium;
generating a page structure map describing a relationship between the received data written to the file and the plurality of transport objects;
receiving a request for a portion of the transport objects;
storing, in a second access memory, pages of data read from the file, wherein the pages stored are determined according to the page structure map as including data corresponding to the requested portion of the transport objects;
decoding the data corresponding to the requested portion of the transport objects using the forward error correction code; and
providing the requested portion of the transport objects for consumption.

12. The method of claim 11, wherein a plurality data generated from different transport objects are stored within different pages within one file on the physical storage medium, with the page structure map providing an indication of which pages store data for which transport objects.

13. The method of claim 11, further comprising:
using an FEC process to recover transport objects from the received data; and
providing at least portions of the recovered transport objects as the requested portion of the transport objects.

14. The method of claim 11, further comprising:
using an FEC process to recover transport objects from data stored in the second access memory in response to requests for portions of those transport objects; and
storing recovered transport objects in the second access memory for use by a requestor.

15. The method of claim 11, wherein at least some of the plurality of transport objects comprise related multimedia content.

16. The method of claim 15, wherein requested portions of the multimedia content are requested in the form of HTTP byte range requests or DASH requests.

17. The method of claim 15, further comprising:
maintaining in the page structure map indications of the multimedia content size, in bytes, an alignment factor, in bytes, a symbol size, in bytes, a number of source blocks of the multimedia content, and a number of transport objects in each source block, wherein sub-blocks are the transport objects and source blocks comprise sub-blocks for which related FEC data has been received.

18. The method of claim 11, further comprising:
storing received data generated from transport objects into the first access memory until a threshold amount of data for a sufficient number of transport objects is received; and
writing a block of pages of data to the physical storage medium corresponding to data received for multiple transport objects, wherein the data written to each page is generated from a single transport object.

19. The method of claim 11, wherein the size of the first access memory is smaller than the size of the plurality of transport objects and wherein the size of the second access memory is smaller than the size of the plurality of transport objects.

20. A receiving device for storing and accessing data from a plurality of transport objects, the data transmitted from a source to the receiving device over a communications channel as data packets in an interleaved transport object order, the receiving device comprising:
a physical storage medium configured to store received data in page format;
a receiving module communicatively coupled to an input of the receiving device and to the physical storage medium, the receiving module having a first access memory and further being configured to receive the received data, store the received data in the first access memory according to a page format in at least a partially de-interleaved format, write the received data formatted in page format sequentially to a file in the physical storage medium communicatively coupled to the receiving module, and generate a page structure map describing a relationship between the received data written to the file and the plurality of transport objects; and
an access module having a second access memory and being communicatively coupled to an application module and to the physical storage medium, the access module further configured to receive a request for portion of the transport objects in a specified order from the application module, determine from the page structure map which of the pages of the file include corresponding data corresponding to the requested portion of the transport objects, read the determined pages from the physical storage medium into the second access memory, and provide the data for the requested portion of the transport objects in the specified order to the application module.

21. The receiving device of claim 20, wherein the physical storage medium is configured such that writes of multiple pages of data to non-sequential locations requires more time than reads of an equal number of pages of data from non-sequential locations and writing multiple pages of data to sequential locations is faster by at least a factor of two than writing an equal number of pages of data to non-sequential locations.

22. The receiving device of claim 20, wherein reception of data received for different transport objects is interleaved.

23. The receiving device of claim 22 wherein the data in each page written to the physical storage medium is data from the same transport object.

24. The receiving device of claim 20, wherein at least a portion of the requested portion of the transport objects corresponds to at least part of one transport object and data from that transport object is stored in at least a portion of the determined pages read from the physical storage medium into the second access memory.

25. The receiving device of claim 20, wherein the aggregate amount of data in the determined pages read from the physical storage medium into the second access memory to recover a requested portion of transport objects is roughly the size of the requested portion of transport objects.

26. The receiving device of claim 20, wherein the size of the first access memory is smaller than the size of the plurality of transport objects and wherein the size of the second access memory is smaller than the size of the plurality of transport objects.

27. A method for storing and accessing data transmitted from a source to a destination over a communications channel, the data generated from a plurality of transport objects, the data transmitted as data packets in an interleaved transport object order, the method comprising:
receiving the received data as data packets;
storing the received data in a first access memory according to a page format having at least some de-interleaving;
writing the received data formatted in the page format from the first access memory to a file in a physical storage medium;
generating a page structure map describing a relationship between the received data written to the file and the transport objects;
receiving a request for a portion of the transport objects;
storing, in a second access memory, pages of data read from the file, wherein the pages stored are determined according to the page structure map as including data corresponding to the requested portion of the transport objects; and providing the requested portion of the transport objects for consumption.

28. The method of claim 27, wherein a plurality data generated from different transport objects are stored within different pages within one file on the physical storage medium, with the page structure map providing an indication of which pages store data for which transport objects.

29. The method of claim 27, wherein requested portions of the transport objects are requested in the form of HTTP byte range requests or DASH requests.

30. The method of claim 27, further comprising:
storing received data generated from transport objects into the first access memory until a threshold amount of data for a sufficient number of transport objects is received; and
writing a block of pages of data to the physical storage medium corresponding to data received for multiple transport objects, wherein the data written to each page is generated from a single transport object.

31. The method of claim 27, wherein the requested portion of the transport objects is provided to the application module at a rate that is at a consumption rate desired by the application module.

32. The method of claim 27, wherein the requested portion of the transport objects is a single transport object.

33. The method of claim 27, further comprising:
determining if sufficient memory and processor time is available for post-storage processing of stored data; and
if sufficient memory and processor time is available, performing background reconstruction of data in stored memory to reorder from a stored order to a playout order.

34. The method of claim 27, wherein the size of the first access memory is smaller than the size of the plurality of transport objects and wherein the size of the second access memory is smaller than the size of the plurality of transport objects.
